(19) United States
(12) Patent Application Publication
(10) Pub. No.: US 2026/0343126 A1
(43) Pub. Date: Oct. 29, 2026

(54) MULTI-AXIS ROTATION AUDIO SOUNDBAR MOUNTING BRACKET FOR WALL MOUNTED DISPLAY

(71) Applicant: Crestron Electronics, Inc., Rockleigh, NJ (US)

(72) Inventor: Donald Florczak, Tenafly, NJ (US)

(73) Assignee: Crestron Electronics, Inc., Rockleigh, NJ (US)

(21) Appl. No.: 19/550,987

(22) Filed: Feb. 26, 2026

Related U.S. Application Data
(60) Provisional application No. 63/765,097, filed on Feb. 28, 2025.

(51) Int. Cl. H04R 1/02; H05K 5/02

(52) U.S. Cl. CPC H04R 1/026; H05K 5/0204; H04R 2201/021; H04R 2400/11

(57) ABSTRACT

A rotational soundbar mounting apparatus for supporting a soundbar relative to a display may include a first rail, a rotational soundbar bracket, a soundbar mounting bracket, a rotating pin, and a locking pin. The first rail may be coupled to the display. The rotational soundbar bracket may be coupled to the first rail. The rotational soundbar bracket may include a soundbar mounting surface and a mounting interface, and the soundbar mounting surface may include a rotating pin receptacle and a plurality of locking pin receptacles. The soundbar mounting bracket may be coupled to the mounting interface and to the soundbar. The rotating pin may be inserted into the rotating pin receptacle to define a rotational axis about which the rotational soundbar bracket is rotatable. The locking pin may be inserted into one of the plurality of locking pin receptacles to restrict rotation of the rotational soundbar bracket.

### PRIORITY INFORMATION

The present application claims priority under 35 U.S.C. § 119 (e) to U.S. Provisional Patent Application Ser. No. 63/765,097, filed Feb. 28, 2025, the entire contents of which are expressly incorporated herein by reference.

### BACKGROUND OF THE INVENTION

### Technical Field

The embodiments described herein relate generally to display mounting systems, and more specifically to systems, methods, and modes for providing a rotational soundbar mounting apparatus that couples to a display wall mounting system and which rotationally mounts a soundbar to the display according to aspects of the embodiments.

### Background Art

It is well known that many enterprises employ conference rooms for meetings. In many of these meetings there will be presentations by one or more of the participants. Typically, these presentations are stored on laptop computers, and the like. It is increasingly common for many of these conference rooms to have highly sophisticated interactive (e.g., those that include remote and/or long distance access) audio-video (AV) conference room systems that can present the subject matter on one or more displays. The AV conference room systems typically include one or more microphones, cameras, and loudspeakers, and one or more devices that interconnects all the other devices with participants' laptops.

Typically, one or more attendees of a meeting in a conference room will want to display something for the benefit of the meeting attendees, and currently available displays will be mounted on convention wall mounting systems that allow for rotation in at least two axes. If there are soundbars available, however, they will often be, if not exclusively, hard mounted in a fixed position. Such fixed mounting environments diminishes the utility of the soundbar in the conference room meeting environment.

Accordingly, a need has arisen for systems, methods, and modes for providing a rotational soundbar mounting apparatus that couples to a display wall mounting system and which rotationally mounts a soundbar to the display according to aspects of the embodiments.

### SUMMARY

It is an object of the embodiments to substantially solve at least the problems and/or disadvantages discussed above, and to provide at least one or more of the advantages described below.

It is therefore a general aspect of the embodiments to provide systems, methods, and modes for providing a rotational soundbar mounting apparatus that couples to a display wall mounting system and which rotationally mounts a soundbar to the display according to aspects of the embodiments that will obviate or minimize problems of the type previously described.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Further features and advantages of the aspects of the embodiments, as well as the structure and operation of the various embodiments, are described in detail below with reference to the accompanying drawings. It is noted that the aspects of the embodiments are not limited to the specific embodiments described herein. Such embodiments are presented herein for illustrative purposes only. Additional embodiments will be apparent to persons skilled in the relevant art(s) based on the teachings contained herein.

According to a first aspect of the embodiments, a rotational soundbar mounting apparatus for supporting a soundbar relative to a display is provided. The apparatus may include a first rail, a rotational soundbar bracket, a soundbar mounting bracket, a rotating pin, and a locking pin. The first rail may be coupled to the display. The rotational soundbar bracket may be coupled to the first rail. The rotational soundbar bracket may include a soundbar mounting surface and a mounting interface, and the soundbar mounting surface may include a rotating pin receptacle and a plurality of locking pin receptacles positioned concentrically around the rotating pin receptacle. The soundbar mounting bracket may be coupled to the mounting interface of the rotational soundbar bracket and to the soundbar. The rotating pin may be inserted into the rotating pin receptacle to define a rotational axis about which the rotational soundbar bracket is rotatable relative to the first rail. The locking pin may be inserted into a selected one of the plurality of locking pin receptacles to restrict rotation of the rotational soundbar bracket relative to the first rail and maintain the rotational soundbar bracket at a selected angular position.

According to an embodiment, the first rail may include a rail rotating hole and a rotation locking hole, and the rotating pin may extend through the rotating hole and may be received by the rotating pin receptacle. The locking pin may extend through the rotation locking hole and the selected one of the plurality of locking pin receptacles.

According to an embodiment, the first rail may include a plurality of substantially circular shaped holes configured to receive fasteners for coupling the first rail to at least one of a wall, the display, a second rail, or another supporting structure.

According to an embodiment, the apparatus may further include a second rail configured to be coupled to the rear side of the display, and the first rail may be coupled to the second rail by fasteners extending through a plurality of substantially circular shaped holes of the first rail and through a plurality of oval shaped holes of the second rail that overlap the plurality of substantially circular shaped holes.

According to an embodiment, the oval shaped holes may permit positional adjustment of the first rail relative to the second rail prior to fully tightening the fasteners.

According to an embodiment, the plurality of locking pin receptacles may be arranged along an imaginary circle centered on the rotational axis defined by the rotating pin receptacle.

According to an embodiment, the plurality of locking pin receptacles may be positioned at a substantially common radial distance from the rotational axis.

According to an embodiment, the plurality of locking pin receptacles may define predetermined angular positions of the rotational soundbar bracket with respect to the rotational axis.

According to an embodiment, the plurality of locking pin receptacles may include a first, a second, and a third locking pin receptacle. A first imaginary line may extend through the second locking pin receptacle and the rotating pin receptacle, and the first locking pin receptacle may be offset from the first imaginary line in a first transverse direction by a first offset angle. The third locking pin receptacle may be offset from the first imaginary line in a second transverse direction opposite the first transverse direction by a second offset angle.

According to another aspect of the embodiments, a rotational soundbar bracket is provided. The rotational soundbar bracket may include a soundbar mounting surface, a mounting bracket interface, a rotating pin receptacle, and a plurality of locking pin receptacles. The mounting bracket interface may be connected to the soundbar mounting surface. The rotating pin receptacle may be disposed on the soundbar mounting surface and configured to receive a rotating pin that defines a rotation axis about which the rotational soundbar bracket is rotatable relative to a supporting component. A plurality of locking pin receptacles may be disposed on the soundbar mounting surface at different angular locations relative to the rotating pin receptacle. The plurality of locking pin receptacles may be adapted to selectively receive a locking pin to restrict rotation of the rotational soundbar bracket relative to the supporting component and maintain the rotational soundbar bracket at a selected angular position.

According to an embodiment, the mounting interface may include a first mounting hole and a second mounting hole adapted to receive fasteners to couple the rotational soundbar bracket to a soundbar mounting bracket.

According to an embodiment, the first mounting hole and the second mounting hole may be aligned with one another along a longitudinal direction of the mounting interface.

According to an embodiment, the soundbar mounting surface may be substantially perpendicular to the mounting bracket interface.

According to an embodiment, the rotating pin receptacle may protrude outwardly from the soundbar mounting surface to receive the rotating pin.

According to an embodiment, the plurality of locking pin receptacles may be disposed at a substantially common radial distance from the rotational axis defined by the rotating pin receptacle.

According to another aspect of the embodiments, a rotational soundbar mounting apparatus for supporting a soundbar relative to a display is provided. The apparatus may include a first rail, a rotational soundbar bracket, a soundbar mounting bracket, a rotating pin, and a locking pin inserted. The first rail may be coupled to the display. The rotational soundbar bracket may be coupled to the first rail, and the rotational soundbar bracket may include a soundbar mounting surface and a mounting bracket interface. The soundbar mounting surface may include a rotating pin receptacle and a curved locking pin slot. The soundbar mounting bracket may be coupled to the mounting bracket interface of the rotational soundbar bracket and coupled to the soundbar. The rotating pin may be inserted into the rotating pin receptacle to define a rotational axis about which the rotational soundbar bracket may be rotatable relative to the first rail. The locking pin may be inserted into the curved locking pin slot to restrict rotation of the rotational soundbar bracket relative to the first rail and maintain the rotational soundbar bracket at a selected angular position.

According to an embodiment, the curved locking pin slot may be arcuate about the rotational axis defined by the rotating pin receptacle such that the curved locking pin slot may be concentric with the rotational axis.

According to an embodiment, the soundbar mounting surface may include a first curved locking pin slot and a second curved locking pin slot, and the locking pin may be configured to be inserted into a selected one of the first curved locking pin slot or the second curved locking pin slot to set the rotational soundbar bracket to the selected angular position.

According to an embodiment, the curved locking pin slot may define a substantially continuous angular adjustment range for the rotational soundbar bracket, and the selected angular position of the rotational soundbar bracket may be continuously selectable within the angular adjustment range by selecting an engagement position of the locking pin along a length of the curved locking pin slot.

According to an embodiment, the first rail may include a rotation locking hole, and the locking pin may extend through the rotation locking hole and the curved locking pin slot to restrict rotation of the rotational soundbar bracket relative to the first rail.

### BRIEF DESCRIPTION OF THE DRAWINGS

The above and other objects and features of the embodiments will become apparent and more readily appreciated from the following description of the embodiments with reference to the following figures. Different aspects of the embodiments are illustrated in reference figures of the drawings. It is intended that the embodiments and figures disclosed herein are to be considered to be illustrative rather than limiting. The components in the drawings are not necessarily drawn to scale, emphasis instead being placed upon clearly illustrating the principles of the aspects of the embodiments. In the drawings, like reference numerals designate corresponding parts throughout the several views.

FIG. 1 illustrates an exploded front isometric view of a rotational soundbar mounting apparatus according to aspects of the embodiments.

FIG. 2 illustrates an exploded rear isometric view of a rotational soundbar mounting apparatus according to aspects of the embodiments.

FIG. 3 illustrates an isometric view of a typical conference room with a display mounted on a wall therein, and with rotational soundbar mounting apparatus attached to the display (not visible) along with a soundbar according to aspects of the embodiments.

FIGS. 4 and 5 illustrate a side view of the display shown in FIG. 3 along line C-C, with the rotational soundbar mounting apparatus visible, as shown in FIGS. 1 and 2, and attached to a conventional wall mounting apparatus according to aspects of the embodiments.

FIG. 6 illustrates a top front isometric view of a display rail that is part of a rotational soundbar mounting apparatus, as shown in FIGS. 1 and 2, according to aspects of the embodiments.

FIG. 7 illustrates a top view of the display rail, as shown in FIG. 6, that is part of the rotational soundbar mounting apparatus, as shown in FIGS. 1 and 2, according to aspects of the embodiments.

FIG. 8 illustrates a front view of the display rail, as shown in FIG. 6, that is part of the rotational soundbar mounting apparatus, as shown in FIGS. 1 and 2, according to aspects of the embodiments.

FIG. 9 illustrates a right-side view of the display rail, as shown in FIG. 6, that is part of the rotational soundbar mounting apparatus, as shown in FIGS. 1 and 2, according to aspects of the embodiments.

FIG. 10 illustrates a top front isometric view of a wall mount rail that is part of a rotational soundbar mounting apparatus, as shown in FIGS. 1 and 2, according to aspects of the embodiments.

FIG. 11 illustrates a top view of the wall mount rail, as shown in FIG. 10, that is part of the rotational soundbar mounting apparatus, as shown in FIGS. 1 and 2, according to aspects of the embodiments.

FIG. 12 illustrates a front view of the wall mount rail, as shown in FIG. 10, that is part of the rotational soundbar mounting apparatus, as shown in FIGS. 1 and 2, according to aspects of the embodiments.

FIG. 13 illustrates a right-side view of the wall mount rail, as shown in FIG. 10, that is part of the rotational soundbar mounting apparatus, as shown in FIGS. 1 and 2, according to aspects of the embodiments.

FIG. 14 illustrates a top front isometric view of a rotational soundbar bracket that is part of a rotational soundbar mounting apparatus, as shown in FIGS. 1 and 2, according to aspects of the embodiments.

FIG. 15 illustrates a top view of the rotational soundbar bracket, as shown in FIG. 14, that is part of the rotational soundbar mounting apparatus, as shown in FIGS. 1 and 2, according to aspects of the embodiments.

FIG. 16 illustrates a front view of the rotational soundbar bracket, as shown in FIG. 14 that is part of the rotational soundbar mounting apparatus, as shown in FIGS. 1 and 2, according to aspects of the embodiments.

FIG. 17 illustrates a left side view of the rotational soundbar bracket, as shown in FIG. 14, that is part of the rotational soundbar mounting apparatus, as shown in FIGS. 1 and 2, according to aspects of the embodiments.

FIG. 18 illustrates a top front isometric view of a soundbar mounting bracket that is part of a rotational soundbar mounting apparatus, as shown in FIGS. 1 and 2, according to aspects of the embodiments.

FIG. 19 illustrates a top view of the soundbar mounting bracket, as shown in FIG. 18, that is part of the rotational soundbar mounting apparatus, as shown in FIGS. 1 and 2, according to aspects of the embodiments.

FIG. 20 illustrates a front view of the soundbar mounting bracket, as shown in FIG. 18, that is part of the rotational soundbar mounting apparatus, as shown in FIGS. 1 and 2, according to aspects of the embodiments.

FIG. 21 illustrates a left side view of the soundbar mounting bracket, as shown in FIG. 18, that is part of the rotational soundbar mounting apparatus, as shown in FIGS. 1 and 2, according to aspects of the embodiments.

FIG. 22 illustrates an exploded rear isometric view of a display with first and second display rails and first and second wall mount rails of the rotational soundbar mounting apparatus ready to be attached to the display in either a bottom mount configuration or a top mount configuration according to aspects of the embodiments.

FIG. 23 illustrates a rear isometric view of a display with first and second display rails and first and second wall mount rails of the rotational soundbar mounting apparatus attached to the display in a bottom mount configuration according to aspects of the embodiments.

FIG. 24 illustrates a rear isometric view of a display with first and second display rails and first and second wall mount rails of the rotational soundbar mounting apparatus attached to the display in a top mount configuration according to aspects of the embodiments.

FIG. 25 illustrates an exploded partial view of a bottom portion of the rotational soundbar mounting apparatus with rotational soundbar brackets according to aspects of the embodiments.

FIG. 26 illustrates a close up view of a first rotational soundbar bracket 106a being mounted to wall mount rail 104a, as shown in FIG. 25, and FIG. 27 is a close up view of a second rotational soundbar bracket 106b being mounted to wall mount rail 104b, as shown in FIG. 25, according to aspects of the embodiments.

FIG. 28 illustrates a front isometric view of soundbar mounting bracket being mounted to first and second rotational soundbar brackets according to aspects of the embodiments.

FIG. 29 illustrates a front isometric view of a soundbar being mounted to the soundbar mounting bracket according to aspects of the embodiments.

FIG. 30 illustrates a front isometric view of a display with rotational soundbar mounting apparatus attached to the display in a top mount configuration according to aspects of the embodiments.

FIG. 31 illustrates a rear view of a display with rotational soundbar mounting apparatus attached to the display in a top mount configuration according to aspects of the embodiments.

FIG. 32 illustrates a left side view of a display with rotational soundbar mounting apparatus attached to the display in a top mount configuration according to aspects of the embodiments.

FIG. 33 illustrates a front view of a display with rotational soundbar mounting apparatus attached to the display in a top mount configuration according to aspects of the embodiments.

FIG. 34 illustrates a front isometric view of a display with rotational soundbar mounting apparatus attached to the display in a bottom mount configuration according to aspects of the embodiments.

FIG. 35 illustrates a rear view of a display with rotational soundbar mounting apparatus attached to the display in a bottom mount configuration according to aspects of the embodiments.

FIG. 36 illustrates a left side view of a display with rotational soundbar mounting apparatus attached to the display in a bottom mount configuration according to aspects of the embodiments.

FIG. 37 illustrates a front view of a display with rotational soundbar mounting apparatus attached to the display in a bottom mount configuration according to aspects of the embodiments.

FIG. 38 illustrates a front isometric view of rotational soundbar bracket being attached to soundbar mounting bracket with fasteners according to aspects of the embodiments.

FIG. 39 illustrates a front view of rotational soundbar bracket according to aspects of the embodiments.

FIG. 40A illustrates a front view of rotational soundbar bracket according to further aspects of the embodiments, and FIG. 40B illustrates a front isometric view of rotational soundbar bracket according to further aspects of the embodiments.

FIG. 41 illustrates a view of wall mount rail, rotational soundbar bracket, soundbar mounting bracket and soundbar in the process of being assembled according to aspects of the embodiments with rotational soundbar bracket being attached to wall mount rail using rotational soundbar bracket locking pin receptacle which orients soundbar in a substantially horizontal configuration.

FIG. 42 illustrates a view of wall mount rail, rotational soundbar bracket, soundbar mounting bracket and soundbar in the process of being assembled according to aspects of the embodiments with rotational soundbar bracket being attached to wall mount rail using rotational soundbar bracket locking pin receptacle which orients soundbar in a downward facing configuration.

FIG. 43 illustrates a view of wall mount rail, rotational soundbar bracket, soundbar mounting bracket and soundbar in the process of being assembled according to aspects of the embodiments with rotational soundbar bracket being attached to wall mount rail using rotational soundbar bracket locking pin receptacle which orients soundbar in a upward facing configuration.

### DETAILED DESCRIPTION

The embodiments are described more fully hereinafter with reference to the accompanying drawings, in which embodiments of the inventive concept are shown. In the drawings, the size and relative sizes of layers and regions may be exaggerated for clarity. Like numbers refer to like elements throughout. The embodiments may, however, be embodied in many different forms and should not be construed as limited to the embodiments set forth herein. Rather, these embodiments are provided so that this disclosure will be thorough and complete, and will fully convey the scope of the inventive concept to those skilled in the art. The scope of the embodiments is therefore defined by the appended claims. The detailed description that follows is written from the point of view of the company that designs, manufactures, markets, and sells home and business audio-video distribution systems, home and business environmental, lighting, shades, and security systems, and audio-video teleconferencing systems, so it is to be understood that generally the concepts discussed herein are applicable to various subsystems and not limited to only a particular device or class of devices, such as display mounting systems, and more particularly to a rotational soundbar mounting apparatus that couples to a display wall mounting system and which rotationally mounts a soundbar according to aspects of the embodiments.

Reference throughout the specification to “one embodiment” or “an embodiment” means that a particular feature, structure, or characteristic described in connection with an embodiment is included in at least one embodiment of the embodiments. Thus, the appearance of the phrases “in one embodiment” or “in an embodiment” in various places throughout the specification is not necessarily referring to the same embodiment. Further, the particular features, structures, or characteristics may be combined in any suitable manner in one or more embodiments.

### LIST OF REFERENCE NUMBERS FOR THE ELEMENTS IN THE DRAWINGS IN NUMERICAL ORDER

TABLE 1
List of Reference Numbers

| | |
|---|---|
| 100 | Rotational Soundbar Mounting |
| | Apparatus (RSMA) that Couples to a |
| | Display Wall Mounting System |
| | and Which Rotationally Mounts a |
| | Soundbar to the Display |
| 102 | Display Rail (DR) |
| 104 | Wall Mount Rail (WMR) |
| 106 | Rotational Soundbar Bracket (RSB) |
| 108 | Soundbar Mounting Bracket (SMB) |
| 110 | Rotating Pin |
| 112 | Locking Pin |
| 114 | Fastener |
| 116 | Soundbar |
| 118 | Mounting Fascia (Fascia) |
| 300 | Conference Room |
| 302 | Display |
| 304a | First Wall |
| 304b | Second Wall |
| 306 | Conference Room Table |
| 402 | Video Electronics Standards |
| | Association (VESA) Wall Mounting System |
| 404 | Acoustic Sound Waves |
| 602 | Upper End DR |
| 604 | Oval Shaped Holes |
| 606 | DR Rib |
| 608 | DR Mounting Portion |
| 610 | DR Alignment Posts |
| 612 | Lower End DR |
| 614a | Upper DR Rotating Hole |
| 614b | Lower DR Rotating Hole |
| 616a | Upper DR Rotation Locking Hole |
| 616b | Lower DR Rotation Locking Hole |
| 1002 | Upper End WMR |
| 1004 | Circular Shaped Holes |
| 1006 | WMR Rib |
| 1008 | WMR Mounting Portion |
| 1012 | Lower End WMR |
| 1014a | Upper WMR Rotating Hole |
| 1014b | Lower WMR Rotating Hole |
| 1016a | Upper WMR Rotation Locking Hole |
| 1016b | Lower WMR Rotation Locking Hole |
| 1402 | RSB Rotating Pin Receptacle |
| 1404 | RSB Locking Pin Receptacle |
| 1406 | RSB SoundBar Mounting Surface |
| 1408 | RSB Mounting Bracket Interface |
| 1410 | RSB Mounting Hole |
| 1802 | Soundbar Horizontal Mounting Surface |
| 1804 | Soundbar Vertical Mounting Surface |
| 1806 | Soundbar Mounting Screw Hole(s) |
| 1808 | Soundbar Mounting Hole(s) |
| 2602 | Upper Mounting Hole |
| 2604 | Lower Mounting Hole |
| 4002 | RSB Locking Pin Slot |

### LIST OF ACRONYMS USED IN THE SPECIFICATION IN ALPHABETICAL ORDER

TABLE 2
List of Acronyms

| | |
|---|---|
| DR | Display Rail |
| RSMA | Rotational Soundbar Mounting Apparatus |
| RSB | Rotational Soundbar Bracket |
| SMB | Soundbar Mounting Bracket |
| VESA | Video Electronics Standards Association |
| WMR | Wall Mount Rail |

The different aspects of the embodiments described herein pertain to the context of systems, methods, and modes for providing a rotational soundbar mounting apparatus that couples to a display wall mounting system and which rotationally mounts a soundbar to the display according to aspects of the embodiments, but is not limited thereto, except as may be set forth expressly in the appended claims.

Crestron Electronics Inc. is one of the world's leading manufacturers of control and automation systems, innovating technology to simplify and enhance modern lifestyles and businesses. Crestron designs, manufactures, and offers for sale integrated solutions to control audio, video, computer, and environmental systems. In addition, the devices and systems offered by Crestron streamlines technology, improving the quality of life in commercial buildings, universities, hotels, hospitals, and homes, among other locations. Accordingly, the systems, methods, and modes for providing a rotational soundbar mounting apparatus that couples to a display wall mounting system and which rotationally mounts a soundbar to the display according to aspects of the embodiments, can be used with virtually any type of wall mounted display and a display wall mounting system that can be manufactured and/or sold by Crestron Electronics Inc., located in Rockleigh, NJ.

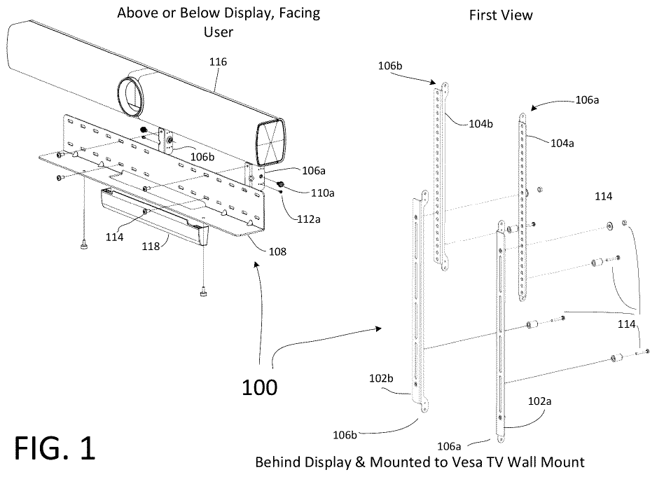

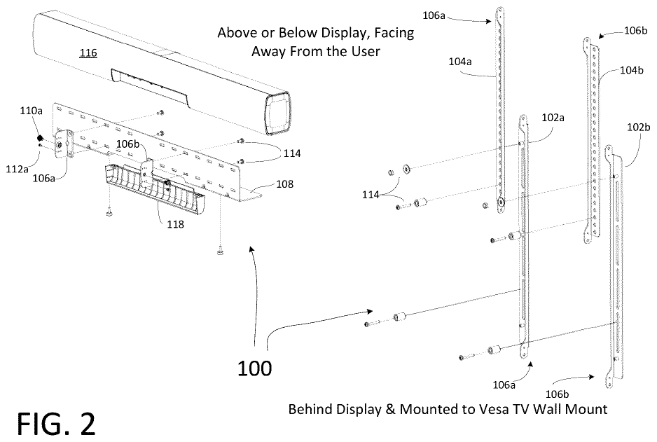

FIG. 1 illustrates an exploded front isometric view of a rotational soundbar mounting apparatus (RSMA) 100 according to aspects of the embodiments, and FIG. 2 illustrates an exploded rear isometric view of a rotational soundbar mounting apparatus 100 according to aspects of the embodiments.

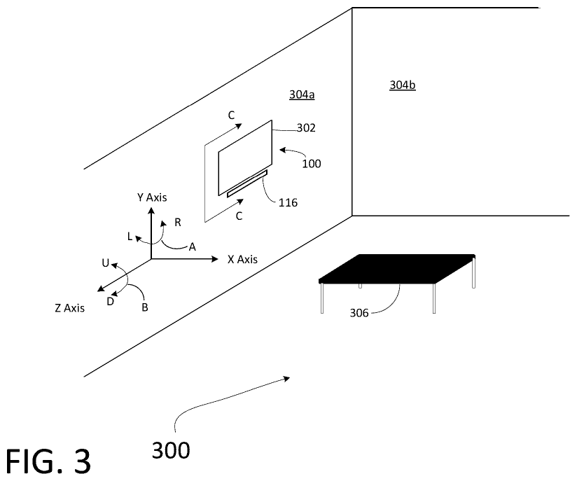

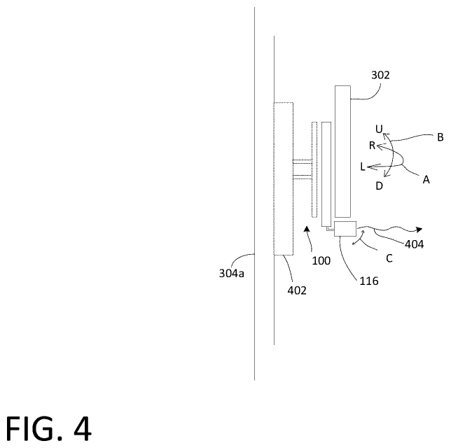

The RSMA 100 comprises display rails (DR) 102a and 102b, wall mount rails (WMR) 104a and 104b, rotational soundbar bracket (RSB) 106, soundbar mounting bracket (SMB) 108, rotating pins 110, locking pins 112, fasteners 114, soundbar 116, and (optionally) mounting fascia (fascia) 118 according to aspects of the embodiments. RSMA 100 provides the ability for the soundbar 116 to be rotationally mounted to the display 302 (shown in FIG. 3) such that if the display 302 were to be rotated up or down, the soundbar 116 can also be rotated up or down to direct acoustic sound waves 404 (shown in FIG. 4) in a desired direction. That is, if it were preferred that the display 302 were to be rotated facing down, the soundbar 116 could be counter-rotated such that acoustic sound waves 404 remained substantially perpendicular to a first wall 304a (shown in FIG. 3), and if the display 302 were to be rotated upwards, the soundbar 116 could be counter-rotated such that acoustic sound waves 404 remained substantially perpendicular to the first wall 304a, according to aspects of the embodiments. Further, even if the display 302 was not rotated, the soundbar 116, through use of RSMA 100, can be rotated up or down as desired according to aspects of the embodiments. As those of skill in the art can appreciate, fasteners 114 can include one or more of screws, bolts, clips, flat washers, lock washers, nylon locking nuts, and all variations and examples thereof, presently available or which will become available, according to aspects of the embodiments. In fulfillment of the dual purposes of clarity and brevity, whenever “fasteners 114” are mentioned herein, those of skill in the art can appreciate that whatever mechanical contrivance that can be used, can or will be used for fastening two or more of the devices/articles described herein together or to one or more walls or surfaces or to other mechanical devices, and a detailed discussion thereof of such fasteners is not necessary for an understanding of the aspects of the embodiments, unless specifically noted and discussed.

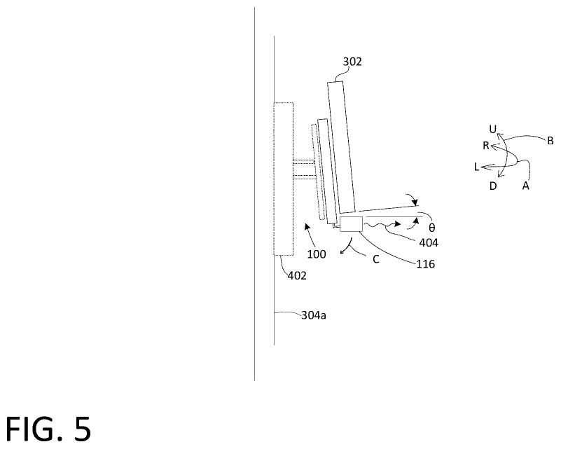

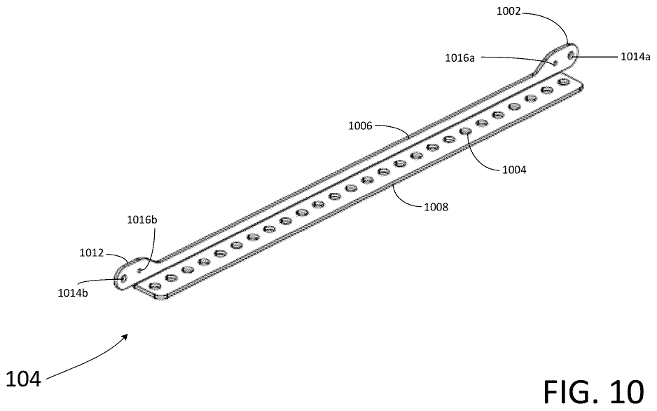

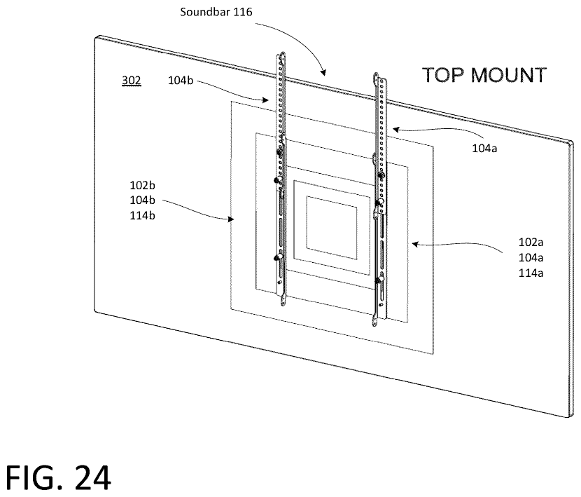

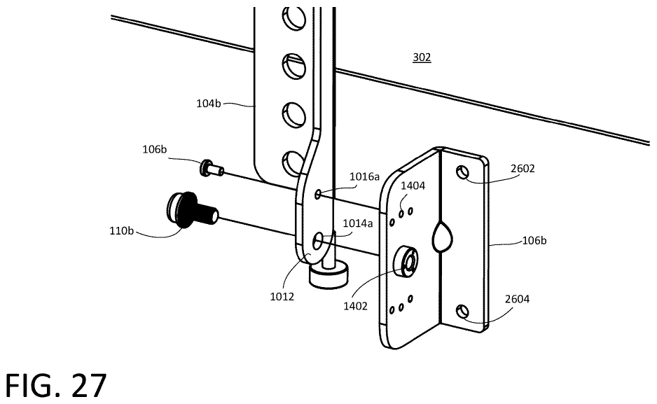

According to aspects of the embodiments, RSMA 100 can be mounted to the rear of the display 302 such that the soundbar 116 is located above the display 302 or below the display 302. The RSMA 100 is located and fastened to the rear of the display 302 by attaching DRs 102a and 102b to the rear of the display 302, and WMRs 104 are attached to DRs 102a and 102b respectively, using fasteners 114 (see FIGS. 22-24). Each of the rails 102 and 104 is functionally symmetrical such that there are no “left” or “right” versions. Each of the rails 102 and 104, further comprise upper and lower ends that are substantially similarly fashioned to each other: that is, each has a rounded upper and lower portion (see, e.g., FIGS. 6-9 regarding DR 102, and FIGS. 10-13 regarding WMR 104). Referring now to FIGS. 6-9, it can be seen that DR 102 comprises an upper end DR 602 and a lower end DR 612. Each of the upper and lower ends 602 and 612 comprise an upper DR rotating hole 614a, and a lower DR rotating hole 614b, respectively, and an upper DR rotation locking hole 616a, and a lower DR rotation locking hole 616b, respectively. The manner in which these rotation and locking holes interface with soundbar 116 are shown in greater detail in FIGS. 25-27, and FIGS. 42-43, and discussed in greater detail below.

In FIGS. 1 and 2, it can be seen that the soundbar 116 can be attached to the soundbar mounting bracket (SMB) 108 with fasteners 114. The fascia 118, which is optional, can be attached to a bottommost portion of the soundbar 116 to cover rotational soundbar brackets (RSB) 106a and 106b. RSBs 106a and 106b are then attached to SMB 108 with fasteners 114.

Referring to FIGS. 1, 2, 22, and 23 (but especially FIG. 22), it can be seen that DRs 102a,b are mounted on to the display 302, and the WMRs 104a,b are mounted onto DRs 102a,b, respectively. According to aspects of the embodiments, DR 102 and WMR 104 are substantially similar to each other in terms of general shape, and especially in regard to the lower and upper ends in terms of the rotating holes 614 (DR 102) and 1014 (WMR 104), and rotation locking holes 616 (DR 102) and 1016 (WMR 104), as shown in FIG. 6 (DR 102) and FIG. 10 (WMR 104). The ends of the DR 102 and WMR 104 are shaped substantially similar to each other. This allows for WMR 104a,b to be optional in cases of smaller displays 302 in which DR 102 is long enough to extend above or below display 302, but also to securely mount the display 302 to VESA wall mounting system 402 as well as have the soundbar 116 mount to it according to aspects of the embodiments.

According to aspects of the embodiments, RSBs 106a and 106b can be rotationally attached to either DR 102a and 102b, respectively, or WMR 104a and 104b, respectively.

FIG. 3 illustrates an isometric view of a typical conference room 300 with the display 302 mounted on a first wall 304a therein, and with the rotational soundbar mounting apparatus 100 attached to the display 302 (not visible) along with the soundbar 116 according to aspects of the embodiments.

Shown in FIG. 3 is a standard, conventional three-dimensional rectangular coordinate system that comprises an X-axis, Y-axis, and Z-axis, in the manner shown in FIG. 3. A conventional Video Electronics Standards Association (VESA) mounting system 402 is mounted behind the display 302, along with rotational soundbar mounting apparatus 100 (both not visible in FIG. 3). If VESA mounting system 402 were to be directly mounted to the display 302, the display 302 would be able to rotate left-right (L-R) about the Y-axis, and up-down (U-D) about the Z-axis, as shown in FIG. 3 by arrows A and B, respectively. Also shown in FIG. 3 is the first wall 304a, upon which the display 302 is mounted, a second wall 304b adjacent to the first wall 304a, and the conference room table 306. As discussed in further detail below, the rotational soundbar mounting apparatus 100 enables the soundbar 116 to be oriented independently of the up-down rotational orientation of the display 302.

FIGS. 4 and 5 illustrate a side view of the display 302 shown in FIG. 3 along line C-C, with rotational soundbar mounting apparatus 100 visible, as shown in FIGS. 1 and 2, and attached to VESA wall mounting system 402 according to aspects of the embodiments.

FIG. 4 illustrates the display 302 in a substantially planar position relative to the first wall 304a, with the soundbar 116 mounted to RSMA 100 and RSMA 100 mounted to VESA wall mounting system 402 according to aspects of the embodiments. Rotational arrows A, B are shown in FIG. 4, illustrating the typical manners in which the display 302 can be rotated with VESA wall mounting system 402. For example, the display 302 may be rotated in an upward direction (in the “U” direction of rotational arrow B) or a downward direction (in the “D” direction of rotational arrow B) through the VESA wall mounting system 402. However, according to aspects of the embodiments, should the display 302 be rotated upwards (in the “U” direction of rotational arrow B) by 0 degrees, as shown in FIG. 5, RSMA 100 provides the means for the soundbar 116, which is mounted thereto, to be rotated in the downward direction (the “D” direction), so that acoustic sound wave 404 can still be directed substantially perpendicular to the first wall 304a. That is, the soundbar 116 can be rotated in the directions of arrow C as shown in FIG. 4 according to aspects of the embodiments. Further, RSMA 100 may be configured to rotate in the upward direction (the “U” direction). According to aspects of the embodiments, should the display 302 be rotated downward (in the “D” direction), RSMA 100 may be rotated in the upward direction (the “U” direction) such that the acoustic sound wave 404 may be emitted from the soundbar 116 in a direction that is substantially perpendicular to the first wall 304a.

FIG. 6 illustrates a top front isometric view of a display rail 102 that is part of a rotational soundbar mounting apparatus 100, as shown in FIGS. 1 and 2, according to aspects of the embodiments.

DR 102 comprises an upper end display rail 602, a plurality of oval shaped holes 604, a DR rib 606, a DR mounting portion 608, DR alignment posts 610, a lower end display rail 612, an upper DR rotating hole 614a, a lower DR rotating hole 614b, an upper DR rotation locking hole 616a, and a lower DR rotation locking hole 616b according to aspects of the embodiments.

The upper end 602 of the display rail 102 and the lower end 612 of the display rail 102 positioned at opposing longitudinal ends of the display rail 102 and collectively form an elongated structural body. The upper end 602 of the display rail 102 and the lower end 612 of the display rail 102 are each configured to be coupled to the rotational soundbar bracket 106. The upper end 602 of the display rail 102 may include the upper display rail rotating hole 614a extending therethrough and the upper display rotation locking hole 616a extending therethrough. In some aspects of the embodiments, a diameter of the upper DR rotating hole 614a may be larger than a diameter of the upper DR rotation locking hole 616a; however, the aspects of the embodiments are not limited thereto. The lower end 612 of the display rail 102 may include the lower display rail rotating hole 614b extending therethrough and the lower display rotation locking hole 616b extending therethrough. In some aspects of the embodiments, a diameter of the lower DR rotating hole 614b may be larger than a diameter of the lower DR rotation locking hole 616b; however, the aspects of the embodiments are not limited thereto.

The plurality of oval shaped holes 604 are formed through the display rail 102 between the upper end display rail 602 and the lower end display rail 612. The oval shaped holes 604 are configured to receive fasteners 114 while allowing positional adjustment of the display rail 102 with the wall mount rail 104 that is coupled to the display rail 102 by means of the fasteners 114. The oval shaped holes 604 may arranged along the length of the display rail 102 and are positioned in the DR mounting portion 608. While four oval shaped holes 604 are illustrated in the display rail 102, this is only an example, and aspects of the embodiments are not limited thereto. The display rail 102 further includes the DR rib 606, which extends along at least a portion of the length of the display rail 102. The DR rib 606 may be substantially perpendicular to the DR mounting portion 608.

The DR mounting portion 608 is formed along a central region of the display rail 102. The DR alignment posts 610 extend in a direction that is substantially perpendicular to the DR mounting portion 608. The DR alignment posts 610 may assist in aligning the display rail 102 with the wall mount rail 104 during assembly. The upper DR rotating hole 614a and the lower DR rotating hole 614b are configured to receive a rotating pin that enables rotational movement of the rotational soundbar bracket relative to the display rail 102. The upper DR rotation locking hole 616a and the lower DR rotation locking hole 616b are configured to receive a locking pin to selectively fix an angular position of the rotational soundbar bracket relative to the display rail 102.

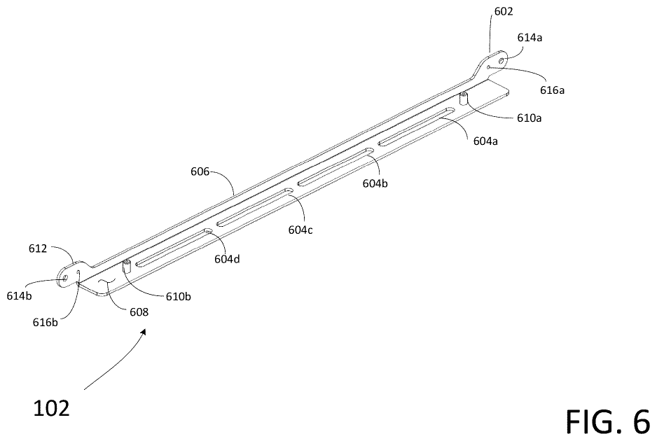

FIG. 7 illustrates a top view of the display rail 102 shown in FIG. 6 that is part of the rotational soundbar mounting apparatus 100 according to aspects of the embodiments.

The upper end 602 of the display rail 102 may extend beyond a first end of the DR mounting portion 608, and the lower end 612 of the display rail 102 may extend beyond a second end of the DR mounting portion 608 that is opposite the first end.

The DR alignment posts 610 include a first DR alignment post 610a and a second DR alignment post 610b that are positioned on the DR mounting portion 608. The first DR alignment post 610a and the second DR alignment post 610b may be spaced apart from one another in a longitudinal direction of the display rail 102. The oval shaped holes 604a, 604b, 604c, and 604d may be arranged between the first and second DR alignment posts 610a and 610b in the longitudinal direction of the display rail 102, and the first and second DR alignment posts 610a and 610b may be arranged between the upper end 602 of the display rail 102 and the lower end 612 of the display rail 102. In some aspects of the embodiments, the first DR alignment post 610a, the second DR alignment post 610b, and one or more of the oval shaped holes 604a, 604b, 604c, and 604d may be substantially aligned along an imaginary line.

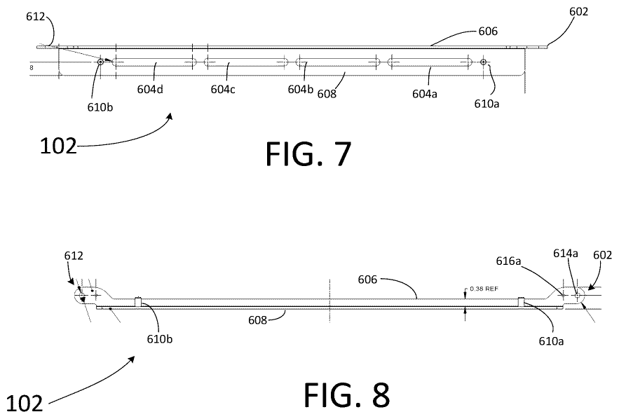

FIG. 8 illustrates a front view of the display rail 102, as shown in FIG. 6, that is part of the rotational soundbar mounting apparatus 100, as shown in FIGS. 1 and 2, according to aspects of the embodiments.

The upper end 602 of the display rail 102 may include the upper DR rotating hole 614a and the upper DR rotation locking hole 616a. The upper DR rotating hole 614a and the upper DR rotation locking hole 616a may be positioned adjacent to one another on the upper end 602 of the display rail 102 such that a rotating pin is receivable in the upper DR rotating hole 614a and a locking pin is receivable in the upper DR rotation locking hole 616a to couple the display rail 102 to the rotational soundbar bracket 106. In some aspects of the embodiments, the first DR alignment post 610a and the second DR alignment post 610b extend from the DR mounting portion 608 in a direction substantially perpendicular to the DR mounting portion 608. The lower end 612 of the display rail 102 may include the lower DR rotating hole 614b and the lower DR rotation locking hole 616b, and the lower DR rotating hole 614b and the lower DR rotation locking hole 616b may be substantially similar to the upper DR rotating hole 614a and the upper DR rotation locking hole 616a, respectively. In some aspects of the embodiments, the upper DR rotating hole 614a and the upper DR rotation locking hole 616a may be substantially aligned with the lower DR rotating hole 614b and the lower DR rotation locking hole 616b.

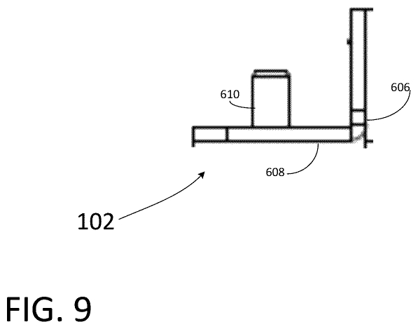

FIG. 9 illustrates a right side view of the display rail 102, as shown in FIG. 6, that is part of the rotational soundbar mounting apparatus 100, as shown in FIGS. 1 and 2, according to aspects of the embodiments.

In FIG. 9, the DR mounting portion 608 is shown with the DR rib 606 extending from the DR mounting portion 608. For example, the DR rib 606 may be substantially perpendicular to the DR mounting portion 608. The DR alignment posts 610 extend from the DR mounting portion 608 and may be positioned adjacent to the DR rib 606. The DR rib 606 and the DR alignment posts 610 may cooperate to promote alignment and to reduce relative movement between the display rail 102 and the wall mount rail 104 during coupling.

FIG. 10 illustrates a top front isometric view of a wall mount rail 104 that is part of a rotational soundbar mounting apparatus 100, as shown in FIGS. 1 and 2, according to aspects of the embodiments.

WMR 104 comprises an upper end wall mount rail 1002, a plurality of substantially circular shaped holes 1004, a WMR rib 1006, a WMR mounting portion 1008, a lower end wall mount rail 1012, an upper WMR rotating hole 1014a, a lower WMR rotating hole 1014b, an upper WMR rotation locking hole 1016a, and a lower WMR rotation locking hole 1016b according to aspects of the embodiments.

The upper end wall mount rail 1002 and the lower end wall mount rail 1012 are positioned at opposing longitudinal ends of the wall mount rail 104 and collectively form an elongated structural body. The upper end wall mount rail 1002 and the lower end wall mount rail 1012 are configured to be coupled to a wall mounting system and to support attachment of a rotational soundbar bracket 106. The upper end wall mount rail 1002 may include the upper WMR rotating hole 1014a extending therethrough and the upper WMR rotation locking hole 1016a extending therethrough. In some aspects of the embodiments, a diameter of the upper WMR rotating hole 1014a may be larger than a diameter of the upper WMR rotation locking hole 1016a; however, the aspects of the embodiments are not limited thereto. The lower end wall mount rail 1012 may include the lower WMR rotating hole 1014b extending therethrough and the lower WMR rotation locking hole 1016b extending therethrough. In some aspects of the embodiments, a diameter of the lower WMR rotating hole 1014b may be larger than a diameter of the lower WMR rotation locking hole 1016b; however, the aspects of the embodiments are not limited thereto.

The plurality of substantially circular shaped holes 1004 are formed through the WMR mounting portion 1008 between the upper end wall mount rail 1002 and the lower end wall mount rail 1012. The substantially circular shaped holes 1004 are configured to receive fasteners that couple the wall mount rail 104 to a wall mounting system or to another structural component. The substantially circular shape of the holes 1004 may limit relative movement between the wall mount rail 104 and each of the wall mounting system and the display rail 102 once the fasteners are secured. While multiple substantially circular shaped holes 1004 are illustrated, this is only an example, and aspects of the embodiments are not limited thereto.

The WMR mounting portion 1008 is formed along a central region of the wall mount rail 104. The WMR rib 1006 extends from the WMR mounting portion 1008 and provides structural reinforcement to the wall mount rail 104. In some aspects of the embodiments, the WMR rib 1006 may be substantially perpendicular to the WMR mounting portion 1008. The WMR rib 1006 may increase rigidity of the wall mount rail 104 and may reduce bending or deformation when the wall mount rail 104 supports the display rail 102, the rotational soundbar bracket 106, and the soundbar 116.

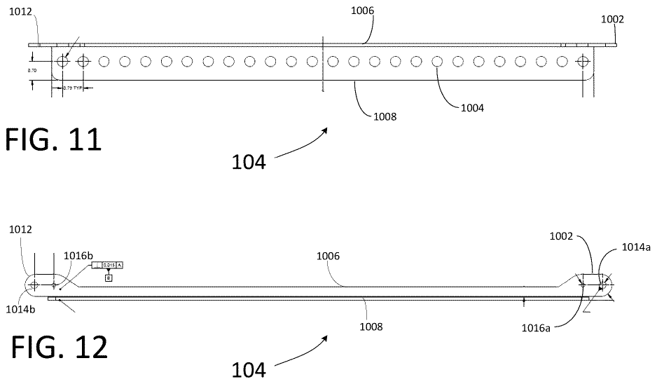

FIG. 11 illustrates a top view of the wall mount rail 104, as shown in FIG. 10, that is part of the rotational soundbar mounting apparatus 100, as shown in FIGS. 1 and 2, according to aspects of the embodiments.

In FIG. 11, the upper end 1002 of the wall mount rail 104 and the lower end 1012 of the wall mount rail 104 define opposing longitudinal ends of the wall mount rail 104. The upper end 1002 of the wall mount rail 104 may extend beyond a first end of the WMR mounting portion 1008, and the lower end 1012 of the wall mount rail 104 may extend beyond a second end of the WMR mounting portion 1008 that is opposite the first end.

The plurality of substantially circular shaped holes 1004 may be arranged along the length of the wall mount rail 104 between the upper end 1002 of the wall mount rail 104 and the lower end 1012 wall mount rail 104. In some aspects of the embodiments, the circular shaped holes 1004 may be arranged along the length of the wall mount rail 104 at a predetermined interval. In some aspects of the embodiments, the substantially circular shaped holes 1004 may have the same diameter as one another; however, aspects of the embodiments are not limited thereto. The substantially circular shaped holes 1004 may be positioned on the WMR mounting portion 1008 and may be spaced apart from one another to receive fasteners that secure the wall mount rail 104 to at least one of, for example, a wall, the display 302, the display rail 102, a wall mounting system, or another supporting structure.

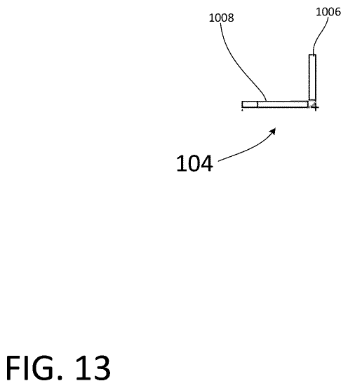

FIG. 12 illustrates a front view of the wall mount rail 104, as shown in FIG. 10, that is part of the rotational soundbar mounting apparatus 100, as shown in FIGS. 1 and 2, according to aspects of the embodiments.

In FIG. 12, the upper end 1002 of the wall mount rail 104 may include the upper WMR rotating hole 1014a and the upper WMR rotation locking hole 1016a. The upper WMR rotating hole 1014a and the upper WMR rotation locking hole 1016a may be positioned adjacent to one another such that a rotating pin and a locking pin are respectively receivable to couple the wall mount rail 104 to a rotational soundbar bracket 106. The lower end 1012 of the wall mount rail 104 may include the lower WMR rotating hole 1014b and the lower WMR rotation locking hole 1016b. The lower WMR rotating hole 1014b and the lower WMR rotation locking hole 1016b may be substantially similar in structure and function to the upper WMR rotating hole 1014a and the upper WMR rotation locking hole 1016a, respectively. In some aspects of the embodiments, the upper WMR rotating hole 1014a and the upper WMR rotation locking hole 1016a may be substantially aligned with the lower WMR rotating hole 1014b and the lower WMR rotation locking hole 1016b.

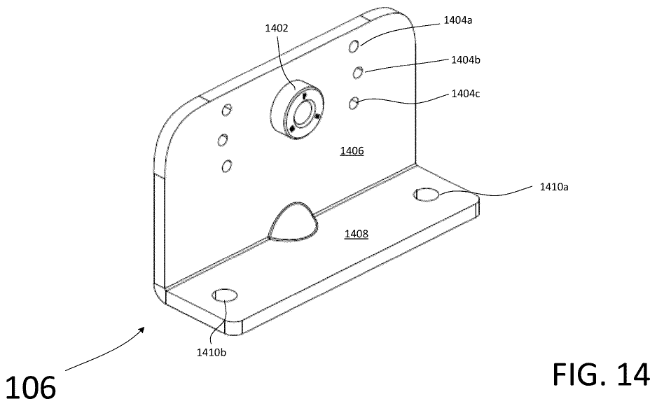

FIG. 13 illustrates a right side view of the wall mount rail 104, as shown in FIG. 10, that is part of the rotational soundbar mounting apparatus 100, as shown in FIGS. 1 and 2, according to aspects of the embodiments.

In FIG. 13, the WMR mounting portion 1008 is shown with the WMR rib 1006 extending from the WMR mounting portion 1008. In some aspects of the embodiments, the WMR rib 1006 may extend in a direction that is substantially perpendicular to the WMR mounting portion 1008. The WMR rib 1006 may increase rigidity of the wall mount rail 104 and may reduce bending or deformation when the wall mount rail 104 supports the display rail 102, the rotational soundbar bracket 106, and the soundbar 116.

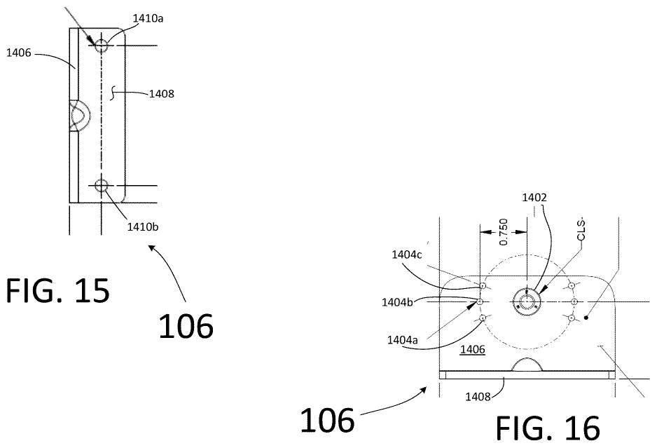

FIG. 14 illustrates a top front isometric view of a rotational soundbar bracket 106 that is part of a rotational soundbar mounting apparatus 100, as shown in FIGS. 1 and 2, according to aspects of the embodiments.

The rotational soundbar bracket 106 includes a RSB soundbar mounting surface 1406 and a RSB mounting bracket interface 1408. The RSB soundbar mounting surface 1406 and the RSB mounting bracket interface 1408 may form an angled bracket structure. For example, the RSB soundbar mounting surface 1406 may be substantially perpendicular to the RSB mounting bracket interface 1408. The RSB mounting bracket interface 1408 includes a first fastener opening 1410a and a second fastener opening 1410b extending therethrough. The first fastener opening 1410a and the second fastener opening 1410b are configured to receive fasteners to couple the rotational soundbar bracket 106 to a soundbar, a soundbar mounting bracket or to a soundbar mounting interface. While two fastener openings are illustrated, aspects of the embodiments are not limited thereto.

The RSB soundbar mounting surface 1406 includes a rotating pin receptacle 1402. The rotating pin receptacle 1402 is configured to receive a rotating pin that defines a rotation axis such that the rotational soundbar bracket 106 is rotatable about the rotating pin relative to a supporting component, such as the display rail 102 or the wall mount rail 104. The RSB soundbar mounting surface 1406 further includes a plurality of locking pin receptacles including a first locking pin receptacle 1404a, a second locking pin receptacle 1404b, and a third locking pin receptacle 1404c. While three locking pin receptacles are illustrated, aspects of the embodiments are not limited thereto. The locking pin receptacles 1404a, 1404b, and 1404c are positioned at different angular locations relative to the rotating pin receptacle 1402 such that, when the rotational soundbar bracket 106 is rotated about the rotating pin, a locking pin is alignable with a selected one of the locking pin receptacles 1404a, 1404b, and 1404c. Receipt of the locking pin in the selected locking pin receptacle 1404a, 1404b, or 1404c may selectively restrict further rotation of the rotational soundbar bracket 106 and may maintain the rotational soundbar bracket 106 at a corresponding angular position relative to the supporting component.

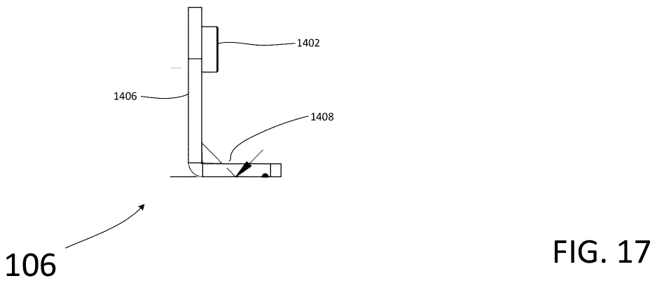

FIG. 15 illustrates a top view of the rotational soundbar bracket 106, as shown in FIG. 14, that is part of the rotational soundbar mounting apparatus 100, as shown in FIGS. 1 and 2, according to aspects of the embodiments.

In FIG. 15, the soundbar mounting portion 1408 is shown with the first fastener opening 1410a and the second fastener opening 1410b extending therethrough. The first fastener opening 1410a and the second fastener opening 1410b may be aligned with one another along a longitudinal direction of the soundbar mounting portion 1408. Alignment of the first fastener opening 1410a and the second fastener opening 1410b may facilitate attachment to the soundbar mounting bracket 108.

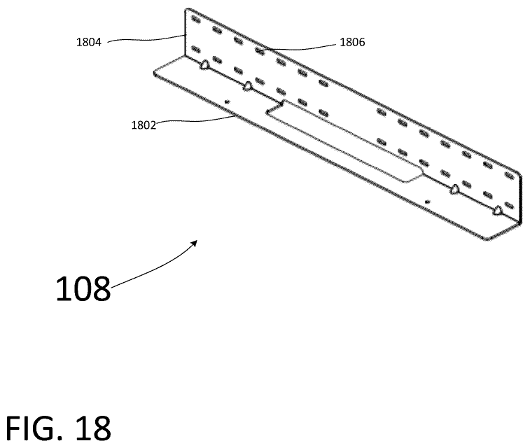

FIG. 16 illustrates a front view of the rotational soundbar bracket 106, as shown in FIG. 14 that is part of the rotational soundbar mounting apparatus 100, as shown in FIGS. 1 and 2, according to aspects of the embodiments.

In FIG. 16, the rotating pin receptacle 1402 is shown on the RSB soundbar mounting surface 1406 and defines a rotational axis of the rotational soundbar bracket 106. The plurality of locking pin receptacles including the first locking pin receptacle 1404a, the second locking pin receptacle 1404b, and the third locking pin receptacle 1404c are positioned at locations spaced from the rotating pin receptacle 1402.

The locking pin receptacles 1404a, 1404b, and 1404c may be arranged along an imaginary circle centered on the rotational axis defined by the rotating pin receptacle 1402. Each of the locking pin receptacles 1404a, 1404b, and 1404c may correspond to a different angular position of the rotational soundbar bracket 106 relative to the supporting component such that engagement of a locking pin with a selected one of the locking pin receptacles 1404a, 1404b, and 1404c maintains the rotational soundbar bracket 106 at a corresponding angular position. In some aspects of the embodiments, the locking pin receptacles 1404a, 1404b, and 1404c may define predetermined angular positions of the rotational soundbar bracket 106 with respect to the rotational axis. In some aspects of the embodiments, the locking pin receptacles 1404a, 1404b, and 1404c may be positioned at a substantially common radial distance from the rotational axis defined by the rotating pin receptacle 1402.

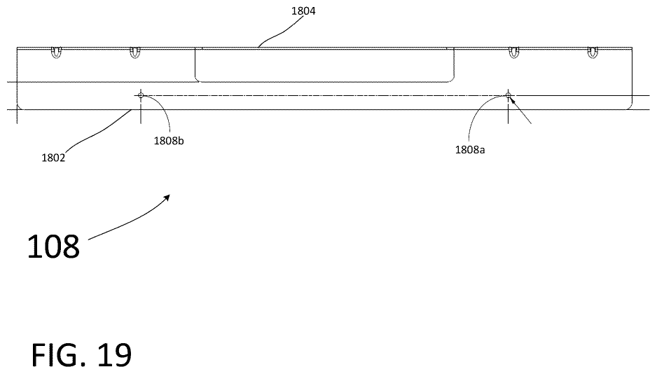

FIG. 17 illustrates a left side view of the rotational soundbar bracket 106, as shown in FIG. 14, that is part of the rotational soundbar mounting apparatus 100, as shown in FIGS. 1 and 2, according to aspects of the embodiments.

In FIG. 17, the RSB soundbar mounting surface 1406 is connected to the soundbar mounting portion 1408. In some aspects of the embodiments, the RSB soundbar mounting surface 1406 may be substantially perpendicular to the soundbar mounting portion 1408.

The rotating pin receptacle 1402 may protrude from the RSB soundbar mounting surface 1406. The rotating pin receptacle 1402 may project outwardly from the RSB soundbar mounting surface 1406 to receive a rotating pin that supports rotational movement of the rotational soundbar bracket 106. However, the present inventive concept is not limited thereto, and in some aspects of the embodiments, the RSB rotating pin receptacle 1402 may be substantially flush with the RSB soundbar mounting surface 1406.

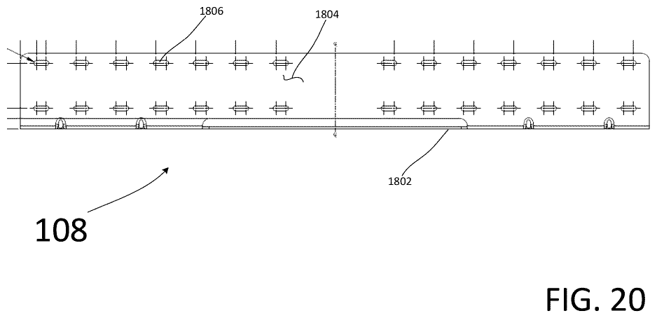

FIG. 18 illustrates a top front isometric view of a soundbar mounting bracket 108 that is part of a rotational soundbar mounting apparatus 100, as shown in FIGS. 1 and 2, according to aspects of the embodiments.

The soundbar mounting bracket 108 includes a soundbar horizontal mounting surface 1802 and a soundbar vertical mounting surface 1804. The soundbar horizontal mounting surface 1802 may be substantially perpendicular to the soundbar vertical mounting surface 1804. The SMB 108 further includes a plurality of soundbar mounting screw holes 1806 formed through the soundbar vertical mounting surface 1804. For example, the screw holes 1806 may be elongated openings configured to receive fasteners. In some aspects of the embodiments, the screw holes 1806 permit positional adjustment of a coupled component relative to the bracket 108 prior to fully securing the fasteners.

In some aspects of the embodiments, the soundbar horizontal mounting surface 1802 may include a region on which the soundbar 116 may be fixed by means of fasteners. The soundbar vertical mounting surface 1804 may be a surface for being coupled to the rotational soundbar brackets 106 by means of fasteners.

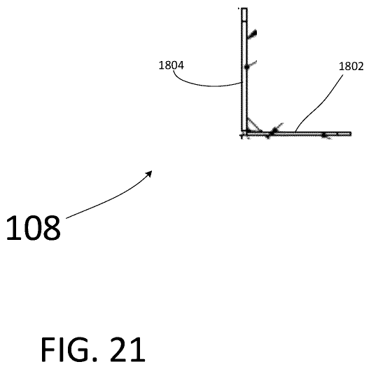

FIG. 19 illustrates a top view of the soundbar mounting bracket 108, as shown in FIG. 18, that is part of the rotational soundbar mounting apparatus 100, as shown in FIGS. 1 and 2, according to aspects of the embodiments.

In FIG. 19, the soundbar horizontal mounting surface 1802 extends along a longitudinal direction of the bracket 108 and includes first and second soundbar mounting holes 1808a and 1808b. The first soundbar mounting hole 1808a and the second soundbar mounting hole 1808b may be aligned with one another along a longitudinal direction of the soundbar horizontal mounting surface 1802. Alignment of the first soundbar mounting hole 1808a and the second soundbar mounting hole 1808b may facilitate attachment to the soundbar 116.

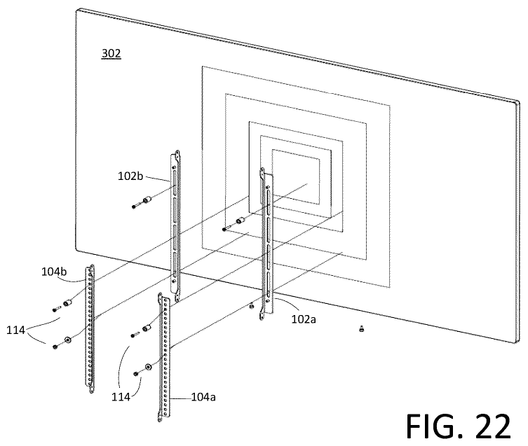

FIG. 20 illustrates a front view of the soundbar mounting bracket 108, as shown in FIG. 18, that is part of the rotational soundbar mounting apparatus 100, as shown in FIGS. 1 and 2, according to aspects of the embodiments.

In FIG. 20, the soundbar vertical mounting surface 1804 extends along a longitudinal direction of the bracket 108 and is positioned above the soundbar horizontal mounting surface 1802. In some aspects of the embodiments, the bracket 108 may be substantially symmetric about an imaginary vertical center line extending in a direction that is substantially perpendicular to the soundbar horizontal mounting surface 1802.

The plurality of soundbar mounting screw holes 1806 are arranged on the soundbar vertical mounting surface 1804. In some aspects of the embodiments, the soundbar mounting screw holes 1806 may be arranged in a plurality of rows and columns on the soundbar vertical mounting surface 1804 to provide multiple fastening locations. In some aspects of the embodiments, the soundbar mounting screw holes 1806 may be symmetrically arranged about the imaginary vertical center line.

In some aspects of the embodiments, the soundbar mounting screw holes 1806 may receive fasteners at selected locations to couple a component such as the rotational soundbar mounting bracket 106 to the bracket 108 while allowing adjustment in at least one direction prior to fully tightening the fasteners.

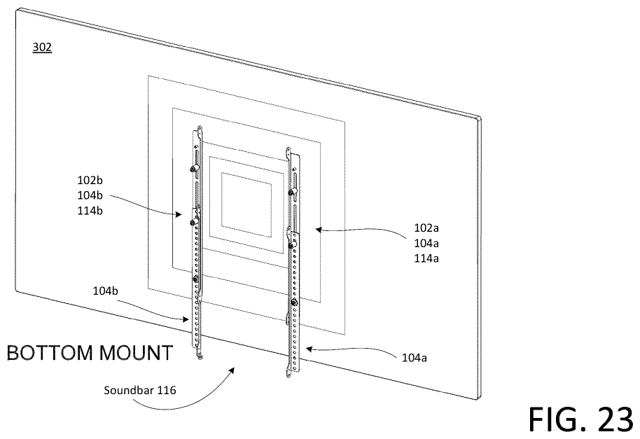

FIG. 21 illustrates a left side view of the soundbar mounting bracket 108, as shown in FIG. 18, that is part of the rotational soundbar mounting apparatus 100, as shown in FIGS. 1 and 2, according to aspects of the embodiments.

In FIG. 21, according to some aspects of the embodiments, the soundbar vertical mounting surface 1804 may be substantially perpendicular to the soundbar horizontal mounting surface 1802. The soundbar mounting bracket 108 may include reinforcement at a junction region between the soundbar horizontal mounting surface 1802 and the soundbar vertical mounting surface 1804 to resist bending or deformation when the soundbar mounting bracket 108 supports the soundbar 116.

FIG. 22 illustrates a rear isometric view of a display with the first and second display rails 102a and 102b and the first and second wall mount rails 104a and 104b of the rotational soundbar mounting apparatus 100 ready to be attached to the display 302 in either a bottom mount configuration or a top mount configuration according to aspects of the embodiments.

The display rails 102a and 102b are configured to be coupled to a rear surface of the display 302. The wall mount rails 104a and 104b are configured to be coupled to the display rails 102a and 102b by means of the fasteners 114. In some aspects of the embodiments, the fasteners 114 extend through corresponding circular shaped holes 1004 of the wall mount rails 104a and 104b and through corresponding oval shaped holes 604 of the display rails 102a and 102b that are aligned with and overlap the circular shaped holes 1004, such that the wall mount rails 104a and 104b, the display 302, and the display rails 102a and 102b are secured to each other. In some aspects of the embodiments, a first pair of the fasteners 114 may be positioned at an upper end region or a lower end region of each display rail 102a and 102b, and one or more additional fasteners 114 may be positioned along a central region of each display rail 102a and 102b, such that the wall mount rails 104a and 104b are coupled to the display rails 102a and 102b at a plurality of spaced apart locations. The oval shaped holes 604 may permit positional adjustment between the wall mount rails 104a and 104b and the display rails 102a and 102b prior to fully tightening the fasteners 114.

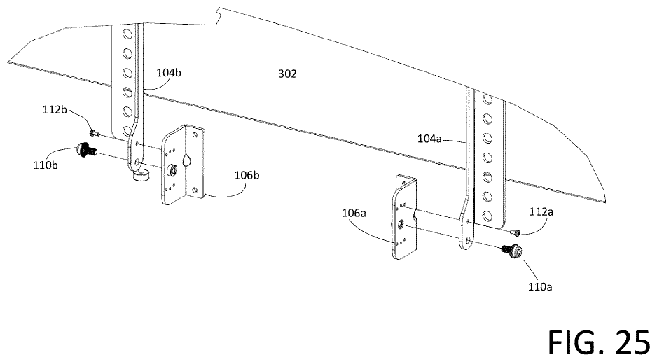

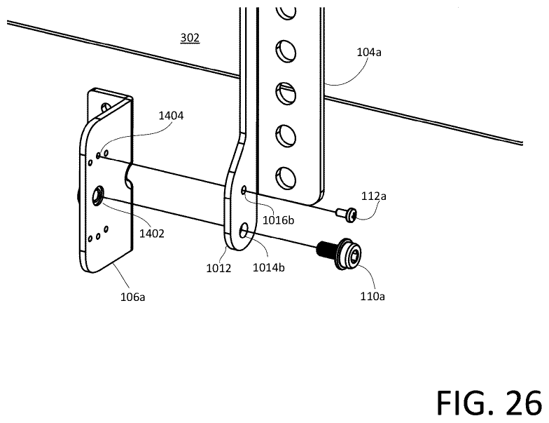

In general, the relative vertical positioning of the display rails 102a and 102b and the wall mount rails 104a and 104b with respect to the display 302 may be selected to define different mounting configurations for the rotational soundbar mounting apparatus 100. In some aspects of the embodiments, portions of the wall mount rails 104a and 104b may extend beyond a lower edge of the display 302 to form a bottom mount configuration, while in other aspects of the embodiments, portions of the wall mount rails 104a and 104b may extend beyond an upper edge of the display 302 to form a top mount configuration. The particular mounting configuration may be selected based on installation preferences, soundbar placement requirements, or display geometry, as described in further detail with reference to FIGS. 23 and 24.

FIG. 23 illustrates a rear isometric view of a display with first and second display rails 102 and first and second wall mount rails 104 of the rotational soundbar mounting apparatus 100 attached to the display in a bottom mount configuration according to aspects of the embodiments.

In the bottom mount configuration, the display rails 102a and 102b are disposed higher than the wall mount rails 104a and 104b. In this configuration, end portions of the wall mount rails 104a and 104b extend below a bottom edge of the display 302 such that the end portions of the wall mount rails 104a and 104b are exposed by the display 302. The exposed end portions of the wall mount rails 104a and 104b provide mounting locations for the rotational soundbar brackets 106 such that a soundbar 116 may be supported below the display 302 through the rotational soundbar brackets 106 and the soundbar mounting bracket 108 coupled to the wall mount rails 104a and 104b.

FIG. 24 illustrates a rear isometric view of a display with first and second display rails 102 and first and second wall mount rails 104 of the rotational soundbar mounting apparatus 100 attached to the display in a top mount configuration according to aspects of the embodiments.

In the top mount configuration, the wall mount rails 104a and 104b are positioned above the display rails 102a and 102b. In this configuration, end portions of the wall mount rails 104a and 104b extend above a top edge of the display 302 such that the end portions of the wall mount rails 104a and 104b are exposed by the display 302. The exposed end portions of the wall mount rails 104a and 104b provide mounting locations for the rotational soundbar brackets 106 such that the soundbar 116 may be supported above the display 302 through the rotational soundbar brackets 106 and the soundbar mounting bracket 108 coupled to the wall mount rails 104a and 104b.

Attention is now directed to FIGS. 25-27, and 41-43.

FIG. 25 illustrates an exploded partial view of a bottom portion of the rotational soundbar mounting apparatus 100 including first and second rotational soundbar brackets 106a and 106b according to aspects of the embodiments. FIG. 25 further illustrates the rotational soundbar mounting apparatus 100 in a bottom mount configuration. However, the arrangement of components shown in FIG. 25 may also be applied to a top mount configuration.

In FIG. 25, the first rotational soundbar bracket 106a and the second rotational soundbar bracket 106b are configured to be rotatably coupled to the first and second wall mount rails 104a and 104b, respectively. The first rotational soundbar bracket 106a is rotatably coupled to the first wall mount rail 104a by a first rotating pin 110a and a first locking pin 112a. The second rotational soundbar bracket 106b is rotatably coupled to the second wall mount rail 104b by a second rotating pin 110b and a second locking pin 112b. In some aspects of the embodiments, the rotating pins 110a and 110b extend through a corresponding wall mount rail rotating hole (e.g., an upper WMR rotating hole 1014a or a lower WMR rotating hole 1014b) of the respective first and second wall mount rails 104a and 104b, and the locking pins 112a and 112b extend through a corresponding wall mount rail rotation locking hole (e.g., an upper WMR rotation locking hole 1016a or a lower WMR rotation locking hole 1016b) of the respective first and second wall mount rails 104a and 104b, such that each rotational soundbar bracket 106 is rotatable about a corresponding rotating pin 110a or 110b and selectively lockable by engagement of a corresponding locking pin 112a or 112b. Which of the upper or lower holes is used may depend on an installation orientation (non-inverted vs inverted) of the respective wall mount rail 104a, 104b (e.g., whether the wall mount rail 104a, 104b is installed in a first orientation or inverted), such that selected holes of the first and second wall mount rails 104a and 104b may be positioned at a common height in the assembled configuration. In some aspects of the embodiments, the wall mount rails 104a and 104b are optionally part of the rotational soundbar mounting apparatus 100, and the first and second rotational soundbar brackets 106a and 106b may be rotatably coupled to the display rails 102a and 102b. In fulfillment of the dual purposes of clarity and brevity, a separate discussion of how the rotational soundbar brackets 106a and 106b can also be attached to the display rails 102a and 102b will not be made, although those of skill in the art can appreciate, based on the discussion above, that such attachments are not only possible but substantially similar in nature, and thus do not necessarily need to be included in order to fully comprehend the nature of the various aspects of the embodiments. This configuration allows an assembly including the soundbar 116, the soundbar mounting bracket 108, and a fascia 118, when used, to be rotated and locked into one of a plurality of angular arrangements. For example, the assembly may be locked at 0 degrees in elevation such that sound waves 404 are directed substantially perpendicular to the first wall 304a, at about 20 degrees in elevation such that sound waves 404 are directed about 20 degrees above an imaginary perpendicular line from the first wall 304a, or at about negative 20 degrees in elevation such that sound waves 404 are directed about 20 degrees below the imaginary perpendicular line from the first wall 304a.

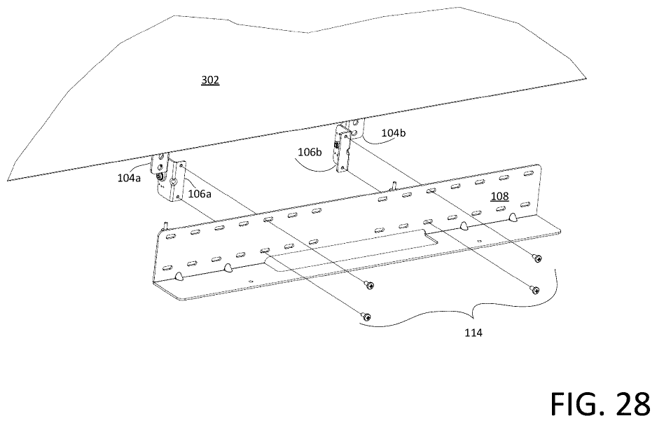

FIG. 26 illustrates a close-up view of the first rotational soundbar bracket 106a being mounted to the first wall mount rail 104a, as shown in FIG. 25, and FIG. 27 illustrates a close-up view of the second rotational soundbar bracket 106b being mounted to the second wall mount rail 104b, as shown in FIG. 25, according to aspects of the embodiments.

In FIG. 26, the first rotational soundbar bracket 106a is rotatably coupled to the first wall mount rail 104a. The first wall mount rail 104a includes a lower WMR rotating hole 1014b and a lower WMR rotation locking hole 1016b. The first rotating pin 110a may be inserted into the lower WMR rotating hole 1014b such that the first rotating pin 110a is received in the rotating pin receptacle 1402 of the first rotational soundbar bracket 106a to define a rotational axis about which the first rotational soundbar bracket 106a may rotate relative to the first wall mount rail 104a. The first locking pin 112a may be inserted into the lower WMR rotation locking hole 1016b such that the first locking pin 112a engages a selected locking pin receptacle 1404 of the first rotational soundbar bracket 106a to selectively restrict rotation. In some aspects of the embodiments, the rotating pin receptacle 1402 of the first rotational soundbar bracket 106a is aligned with the lower WMR rotating hole 1014b when the first rotational soundbar bracket 106a is coupled to the first wall mount rail 104a.

In FIG. 27, the second rotational soundbar bracket 106b is rotatably coupled to the second wall mount rail 104b in a manner substantially similar to the configuration shown in FIG. 26. The second wall mount rail 104b includes an upper wall mount rail rotating hole 1014a and an upper wall mount rail rotation locking hole 1016a. The second rotating pin 110b may be inserted into the upper wall mount rail rotating hole 1014a and received in the rotating pin receptacle 1402 to support rotation of the second rotational soundbar bracket 106b. The second locking pin 112b may be inserted into the upper wall mount rail rotation locking hole 1016a and may engage a selected locking pin receptacle 1404 to selectively restrict rotation. In some aspects of the embodiments, the second rotational soundbar bracket 106b further includes mounting holes 2602 and 2604 configured to receive fasteners for coupling the rotational soundbar bracket 106b to the soundbar mounting bracket 108.

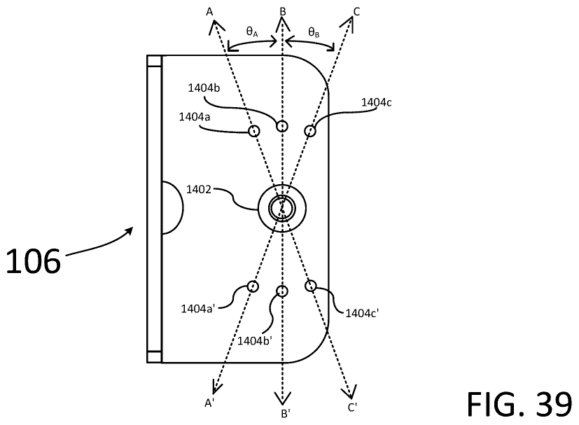

Further details are described with reference to FIGS. 38, 39, and 41 through 43.

FIG. 38 illustrates a front isometric view of the RSB 106 being attached to soundbar mounting bracket 108 with fasteners 114 according to aspects of the embodiments. FIG. 38 also illustrates that the RSB 106 is attached to a rear surface of the soundbar mounting bracket 108 by means of the fasteners. The fasteners 114 may be inserted into corresponding soundbar mounting screw holes 1806 and RSB mounting holes 1410a and 1410b to form the attachment between the RSB 106 and the soundbar mounting bracket 108. It is to be understood that the first and second WMRs 104a and 104b are omitted from FIG. 38 for clarity and ease of understanding.

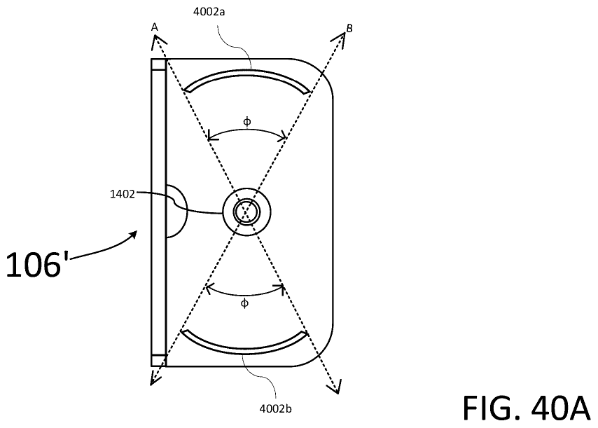

FIG. 39 illustrates a front view of the RSB 106 according to aspects of the embodiments. In FIG. 39, an imaginary vertical reference line B extends through the RSB rotating pin receptacle 1402. In some aspects of the embodiments, the RSB locking pin receptacle 1404b is disposed on (i.e., substantially aligned with) the imaginary vertical reference line B such that the RSB locking pin receptacle 1404b is substantially vertically aligned with the RSB rotating pin receptacle 1402. The RSB locking pin receptacle 1404a is offset from the imaginary vertical reference line B in a first transverse direction (e.g., to the left in this view) by a first offset angle θA, and the RSB locking pin receptacle 1404c is offset from the imaginary vertical reference line B in a second transverse direction opposite the first transverse direction (e.g., to the right in this view) by a second offset angle θB.

In some aspects of the embodiments, an imaginary reference line A extends through the RSB rotating pin receptacle 1402 and the RSB locking pin receptacle 1404a, and an imaginary reference line C extends through the RSB rotating pin receptacle 1402 and the RSB locking pin receptacle 1404c. The first offset angle θA may be defined between the imaginary reference line A and the imaginary vertical reference line B, and the second offset angle θB may be defined between the imaginary vertical reference line B and the imaginary reference line C. The first and second offset angles θA and θB may each be about 20 degrees, may each range from about 19 degrees to about 21 degrees, or may each range from about 18 degrees to about 22 degrees. Other angular offsets may also be used, and more than three RSB locking pin receptacles 1404 may be provided according to aspects of the embodiments.

In some aspects of the embodiments, the locking pin receptacles 1404a, 1404b, and 1404c are positioned along an imaginary circle centered on the rotating pin receptacle 1402, such that the locking pin receptacles 1404a, 1404b, and 1404c are disposed at a substantially common radial distance from the rotational axis defined by the rotating pin receptacle 1402.

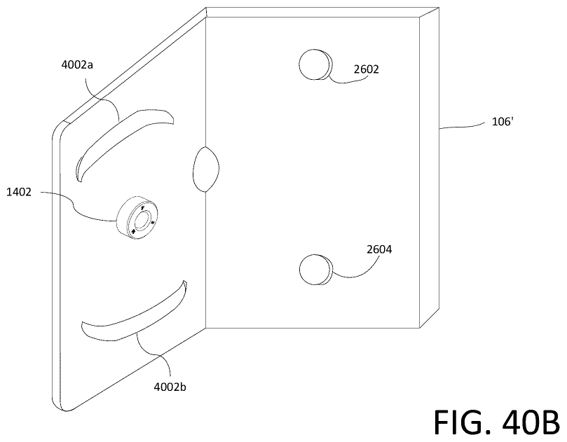

FIG. 40A illustrates a front view of RSB 106′ according to further aspects of the embodiments, and FIG. 40B illustrates a front isometric view of RSB 106′ according to further aspects of the embodiments. In the embodiment of RSB 106′, the RSB locking pin receptacles 1404 (e.g., 1404a-1404c) have been replaced with RSB locking pin slots 4002a and 4002b. In some aspects of the embodiments, the locking pin slots 4002a and 4002b are arcuate slots configured to receive a locking pin (e.g., locking pin 112) such that the locking pin may engage a selected position along a selected locking pin slot 4002a or 4002b to thereby selectively lock RSB 106′ at a selected angular orientation relative to a wall mount rail (e.g., WMR 104). In some aspects of the embodiments, each curved locking pin slot 4002a and 4002b is arcuate about the rotational axis defined by the rotating pin receptacle 1402. In some aspects of the embodiments, a center of curvature of the curved locking pin slot 4002a or 4002b lies on the rotational axis, such that the curved locking pin slot 4002a or 4002b is concentric with the rotational axis. The locking pin slots 4002a and 4002b include an upper locking pin slot 4002a, which is provided above the RSB rotating pin receptacle 1402, and a lower locking pin slot 4002b, which is provided below the RSB rotating pin receptacle 1402.

In FIG. 40A, an imaginary reference line A extends through the RSB rotating pin receptacle 1402 and a first end portion of a locking pin slot (e.g., an end portion of locking pin slot 4002a), and an imaginary reference line B extends through the RSB rotating pin receptacle 1402 and a second end portion of the locking pin slot (e.g., an opposite end portion of locking pin slot 4002a). An angular range of angles φ extends between the imaginary reference lines A and B. In some aspects of the embodiments, an angle φ may correspond to a selected rotational angle of the RSB 106′ and may be defined between (i) one of the reference lines A or B and (ii) an imaginary line extending through the locking pin (or a point of engagement between the locking pin and the locking pin slot) and through the RSB rotating pin receptacle 1402. As the locking pin engages different positions along the selected locking pin slot 4002a or 4002b, the selected angle φ may be continuously adjustable between the limits defined by reference lines A and B.

In some aspects of the embodiments, the above-described angular range and definition of angle φ may apply to each of the locking pin slots 4002a and 4002b such that the locking pin may engage a selected position along the first locking pin slot 4002a or a selected position along the second locking pin slot 4002b to selectively lock the RSB 106′ at a selected angle. In some aspects of the embodiments, the angular range between reference lines A and B may be about 40 degrees total (i.e., about +20 degrees), may range from about +19-21 degrees, or may range from about +18-22 degrees, such that a substantially continuous range of angles φ within the angular range is selectable to rotate the soundbar 116 according to aspects of the embodiments.

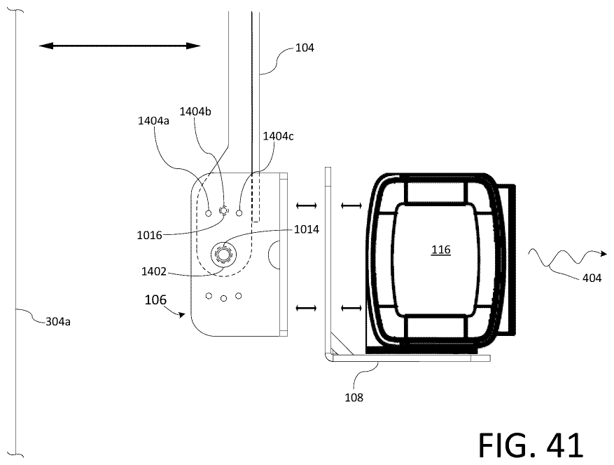

FIG. 41 illustrates a view of the WMR 104, the RSB 106, the SMB 108, and the soundbar 116 during assembly according to aspects of the embodiments, with the RSB 106 locked to the WMR 104 in a substantially horizontal configuration by engagement of a locking pin with both the WMR rotation locking hole 1016 and the RSB locking pin receptacle 1404b. In some aspects of the embodiments, the locking pin is inserted such that it extends through the WMR rotation locking hole 1016 and into the RSB locking pin receptacle 1404b (or vice versa, inserted through the RSB locking pin receptacle 1404b and into/through the WMR rotation locking hole 1016) to restrict rotation of the RSB 106 relative to the WMR 104. When the locking pin extends through both the WMR rotation locking hole 1016 and the RSB locking pin receptacle 1404b, the RSB locking pin receptacle 1404b is disposed substantially vertically above the RSB rotating pin receptacle 1402 such that acoustic sound waves 404 are directed substantially perpendicular from the first wall 304a.

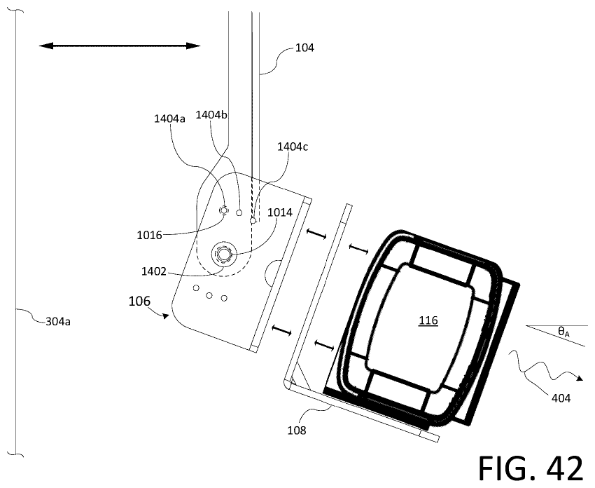

FIG. 42 illustrates a view of the WMR 104, the RSB 106, the SMB 108, and the soundbar 116 in the process of being assembled according to aspects of the embodiments. The RSB 106 may be selectively locked to the WMR 104 using the RSB locking pin receptacle 1404a to orient the soundbar 116 about 20 degrees below a substantially horizontal configuration. In some aspects of the embodiments, the soundbar 116 is attached to the SMB 108, the SMB 108 is attached to the RSB 106, and the RSB 106 is rotatably coupled to the WMR 104 via rotating pin 110 received in the RSB rotating pin receptacle 1402. To lock the RSB 106 at the downward-facing orientation, a locking pin (e.g., locking pin 112) is inserted such that the locking pin extends through both the WMR rotation locking hole 1016 and the selected RSB locking pin receptacle 1404a (or vice versa), thereby restricting rotation of the RSB 106 relative to the WMR 104. In some aspects of the embodiments, the locking pin receptacle 1404a is offset from the imaginary vertical reference line B (as described with reference to FIG. 39) by an offset angle θA (e.g., about 20 degrees), such that, when the locking pin extends through the WMR rotation locking hole 1016 and the RSB locking pin receptacle 1404a, acoustic sound waves 404 are directed at a downward angle relative to an imaginary line perpendicular to the first wall 304a (e.g., about 20 degrees below the imaginary line that is perpendicular to the first wall 304a).

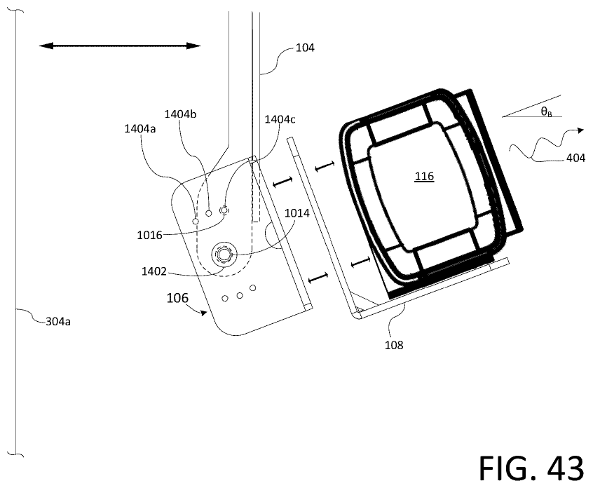

FIG. 43 illustrates a view of the WMR 104, the RSB 106, the SMB 108, and the soundbar 116 in the process of being assembled according to aspects of the embodiments. The RSB 106 may be selectively locked to the WMR 104 using the RSB locking pin receptacle 1404c to orient the soundbar 116 about 20 degrees above a substantially horizontal configuration. In some aspects of the embodiments, the soundbar 116 is attached to the SMB 108, the SMB 108 is attached to the RSB 106, and the RSB 106 is rotatably coupled to the WMR 104 about rotating pin 110 received in the RSB rotating pin receptacle 1402. To lock the RSB 106 at the upward-facing orientation, a locking pin (e.g., locking pin 112) is inserted such that the locking pin extends through both the WMR rotation locking hole 1016 and the selected RSB locking pin receptacle 1404c (or vice versa), thereby restricting rotation of the RSB 106 relative to the WMR 104. In some aspects of the embodiments, the locking pin receptacle 1404c is offset from the imaginary vertical reference line B (as described with reference to FIG. 39) by an offset angle θB (e.g., about 20 degrees), such that, when the locking pin extends through hole 1016 and receptacle 1404c, acoustic sound waves 404 are directed at an upward angle relative to an imaginary line perpendicular to the first wall 304a (e.g., about 20 degrees above the imaginary line that is perpendicular to the first wall 304a).

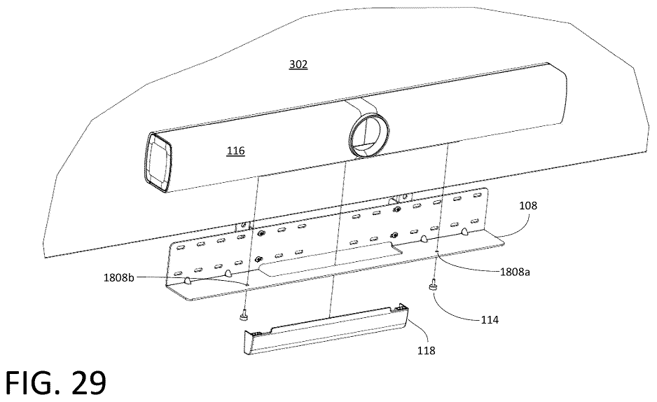

FIG. 28 illustrates an exploded view of soundbar mounting bracket 108 being mounted to first and second rotational soundbar brackets 106a and 106b according to aspects of the embodiments. In the present embodiment, the display 302 is mounted to the first and second wall mount rails (WMRs) 104a and 104b, and the first and second RSBs 106a and 106b are respectively coupled to the first and second WMRs 104a and 104b. The SMB 108 is positioned below the display 302 and aligned to be coupled to the RSBs 106a and 106b.

The SMB 108 is fixed to the RSBs 106a and 106b by one or more fasteners 114. In some aspects of the embodiments, the fasteners 114 are inserted through corresponding SMB mounting screw holes 1806 of the SMB 108 and through corresponding RSB mounting holes 1410 (e.g., 1410a and 1410b) of each RSB 106a and 106b to secure the SMB 108 to the RSBs 106a and 106b. In this manner, when the fasteners 114 are installed, the SMB 108 is mechanically coupled to (and supported by) the RSBs 106a and 106b such that an attached soundbar (not shown in FIG. 28) may be supported.

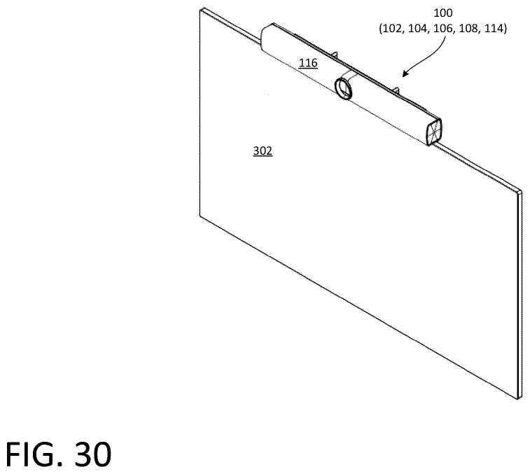

FIG. 29 illustrates an exploded view of a soundbar 116 and the soundbar mounting bracket (SMB) 108 according to aspects of the embodiments. As shown, the soundbar 116 is positioned relative to the SMB 108 such that one or more fasteners 114 can be used to couple the soundbar 116 to the SMB 108. For example, the soundbar 116 may be disposed on and fixed to the soundbar horizontal mounting surface 1802 of the SMB 108. In some aspects of the embodiments, the fasteners 114 are inserted through corresponding soundbar mounting holes 1808a and 1808b of the SMB 108 and engage corresponding fastener-receiving structures (e.g., threaded openings) of the soundbar 116 such that, when tightened, the soundbar 116 is fixed to the SMB 108.

FIG. 29 further illustrates a mounting fascia 118 positioned relative to the SMB 108. In some aspects of the embodiments, the mounting fascia 118 is coupled to the SMB 108 to at least partially conceal the fasteners 114 and/or to provide an aesthetic finish, and in some implementations the mounting fascia 118 is removably coupled to the SMB 108. For example, the mounting fascia 118 may be coupled to the SMB 108 (e.g., to a lower surface of the soundbar horizontal mounting surface 1802). By way of example, the mounting fascia 118 may be removably coupled to the SMB 108 using one or more snap-fit features (e.g., tabs, clips, or detents) that engage corresponding openings or edges of the SMB 108. As another example, the fascia 118 may be coupled to the SMB 108 by engagement with one or more of the fasteners 114 (e.g., captured between a fastener head and the SMB 108 or coupled to the fastener head), such that removal of the one or more fasteners 114 permits removal of the fascia 118. As another example, the fascia 118 may be magnetically coupled to the SMB 108 (e.g., the mounting fascia 118 may include one or more ferromagnetic plates and/or magnets, and the SMB 108 may include one or more magnets and/or ferromagnetic plates to provide a magnetic attraction force that removably retains the mounting fascia 118 on the SMB 108). As another example, the fascia 118 may be coupled to the SMB 108 using an adhesive (e.g., pressure-sensitive adhesive) or other attachment mechanism. At least one of these mounting methods may be used, alone or in combination, for mounting the fascia 118 to the SMB 108.

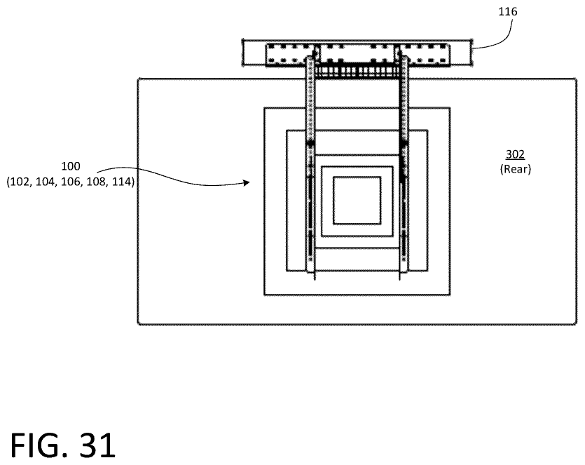

FIG. 30 illustrates a front isometric view of the display 302 with the rotational soundbar mounting apparatus 100 attached to the display 302 in a top mount configuration according to aspects of the embodiments. As shown, the rotational soundbar mounting apparatus 100 supports the soundbar 116 positioned above an upper edge of the display 302. In some aspects of the embodiments, the rotational soundbar mounting apparatus 100 includes one or more display rails 102, one or more wall mount rails (WMRs) 104, one or more rotational soundbar brackets (RSBs) 106, a soundbar mounting bracket (SMB) 108, and one or more fasteners 114 for supporting and retaining the soundbar 116 relative to the display 302. In some aspects of the embodiments, one of the display rails 102 or the WMRs 104 might not be included in the apparatus 100.

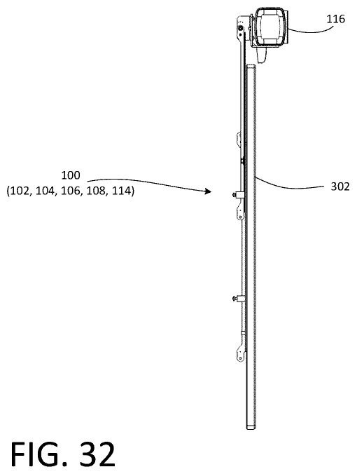

FIG. 31 illustrates a rear view of a display 302 with rotational soundbar mounting apparatus 100 attached to the display 302 in a top mount configuration according to aspects of the embodiments. In FIG. 31, one or more WMRs 104 are coupled to a rear side of the display 302, and one or more RSBs 106 are coupled to the one or more WMRs 104 such that the one or more RSBs 106 are positioned above the upper edge of the display 302. In some aspects of the embodiments, display rails 102 may be attached to the rear side of the display 302 and coupled to end portions of the WMRs 104. The SMB 108 is coupled to the one or more RSBs 106 (e.g., via fasteners 114) such that the SMB 108 is positioned above the upper edge of the display 302, and the soundbar 116 is supported by and coupled to the SMB 108 above the upper edge of the display 302.

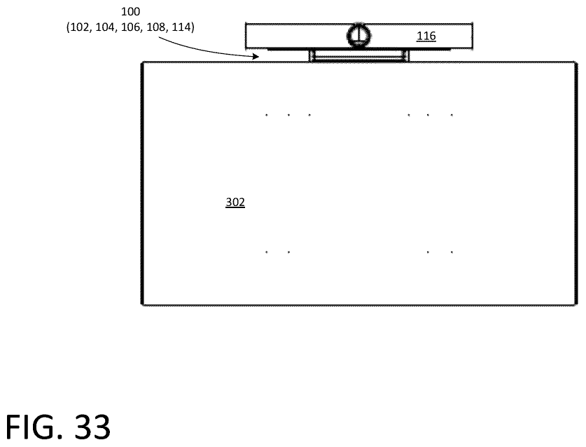

FIG. 32 illustrates a left side view of the display 302 with the rotational soundbar mounting apparatus 100 attached to the display 302 in a top mount configuration according to aspects of the embodiments. In this view, the soundbar 116 is supported above the display 302 by the SMB 108 and the one or more RSBs 106 coupled to the one or more WMRs 104.

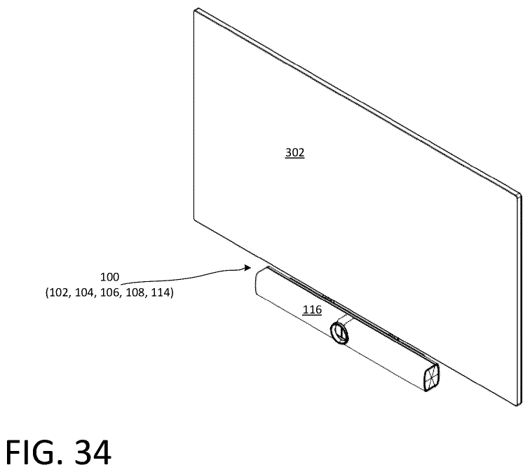

FIG. 33 illustrates a front view of a display 302 with rotational soundbar mounting apparatus 100 attached to the display 302 in a top mount configuration according to aspects of the embodiments. As shown, the soundbar 116 is supported above the display 302 and is coupled to the SMB 108, and the SMB 108 is coupled to one or more RSBs 106 that are coupled to one or more WMRs 104. In some aspects of the embodiments, the apparatus 100 positions the soundbar 116 generally centered relative to the display 302 and supports the soundbar 116 at a selected angular orientation as described herein.

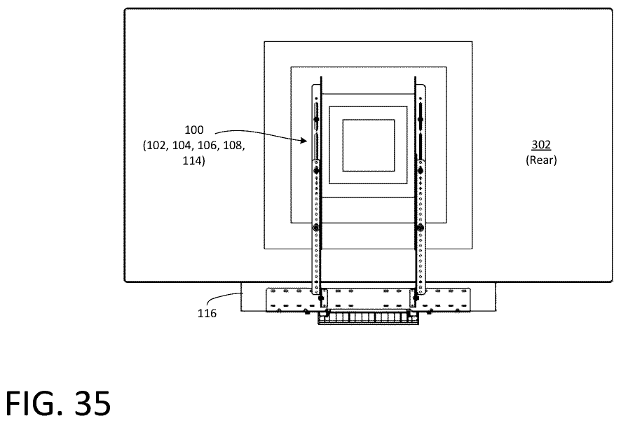

FIG. 34 illustrates a front isometric view of the display 302 with the rotational soundbar mounting apparatus 100 attached to the display 302 in a bottom mount configuration according to aspects of the embodiments. In the bottom-mount configuration, the mounting apparatus 100 supports the soundbar 116 along a lower portion of the display 302 such that the soundbar 116 is disposed below the display 302 when viewed from the front.

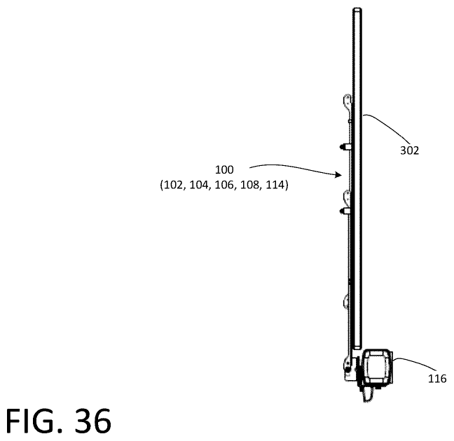

FIG. 35 illustrates a rear view of a display 302 with the rotational soundbar mounting apparatus 100 attached to the display 302 in a bottom-mount configuration according to aspects of the embodiments. In some aspects of the embodiments, the mounting apparatus 100 is coupled to a rear side of the display 302 and supports the soundbar 116 below a lower edge of the display 302. One or more WMRs 104 are coupled to the rear side of the display 302, and one or more RSBs 106 are coupled to the one or more WMRs 104 such that the one or more RSBs 106 are positioned below the lower edge of the display 302. In some aspects of the embodiments, display rails 102 may be attached to the rear side of the display 302 and coupled to end portions of the WMRs 104. The SMB 108 is coupled to the one or more RSBs 106 (e.g., via fasteners 114) such that the SMB 108 is positioned below the lower edge of the display 302, and the soundbar 116 is supported by and coupled to the SMB 108 below the lower edge of the display 302.

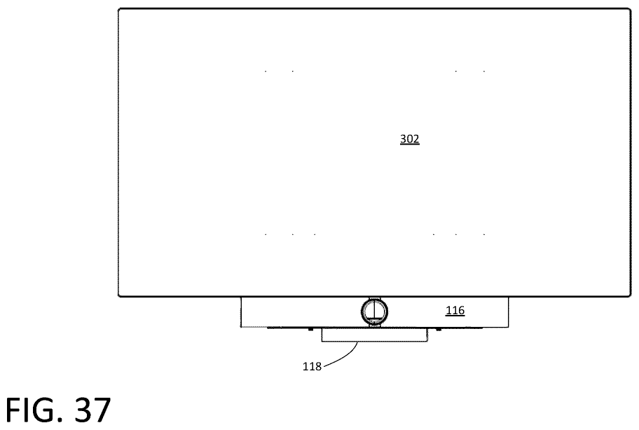

FIG. 36 illustrates a left side view of a display with rotational soundbar mounting apparatus 100 attached to the display in a bottom mount configuration according to aspects of the embodiments. In this view, the soundbar 116 is supported below the display 302 by the SMB 108 and the one or more RSBs 106 coupled to the one or more WMRs 104.

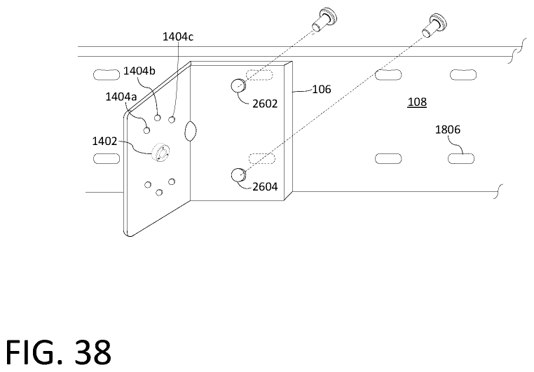

FIG. 37 illustrates a front view of display 302 with the rotational soundbar mounting apparatus 100 attached to the display 302 in the bottom-mount configuration according to aspects of the embodiments. As shown, the soundbar 116 is disposed below the display 302 and is coupled to the SMB 108, and the SMB 108 is coupled to one or more RSBs 106 that are coupled to one or more WMRs 104. In some aspects of the embodiments, the apparatus 100 positions the soundbar 116 generally centered relative to the display 302 and supports the soundbar 116 at a selected angular orientation as described herein. The mounting fascia 118 is positioned along a lower portion of the soundbar 116 and/or mounting apparatus 100 to provide an aesthetic finish and/or to at least partially conceal one or more mounting features (e.g., fasteners and/or bracket structures) associated with mounting the soundbar 116.

As discussed in regard to one or more of the Figures described herein, reference is made to several dimensions (which may include, but is not limited to radii, angles, height, size, volume, among dimensional descriptors), as well as relative positions and/or locations. Those of skill in the art can appreciate that although examples and/or discussions of dimensions/positions/locations are provided, these should not be taken in a limiting manner except as otherwise noted. That is, the aspects of the embodiments are not to be construed as defined or limited by the specific example of the dimensions/positions/locations shown and discussed, but instead are provided merely for illustrating an example of what a device that incorporates the aspects of the embodiments could, in a non-limiting manner, looks like and/or is arranged. Furthermore, as those of skill in the art can appreciate, since the aspects of the embodiments are directed towards a physical object, with dimensions/positions/locations characteristics, all of the parts will have various dimensions/positions/locations, some of which are not shown in fulfillment of the dual purposes of clarity and brevity. According to still further aspects of the embodiments, some of these objects will have dimensions/positions/locations characteristics that lend themselves to aesthetic aspects; in fulfillment of the dual purposes of clarity and brevity, dimensions/positions/locations in this regard may have been omitted. Therefore, as the aspects of the embodiments are directed towards systems, methods, and modes for providing a rotational soundbar mounting apparatus that couples to a display wall mounting system and which rotationally mounts a soundbar to the display according to aspects of the embodiments, it is to be understood that some of the dimensions/positions/locations of the different objects have been shown and some dimensions/positions/locations have not been shown, and the inclusion and/or exclusion should be understood by those of skill in the art especially in view of the discussion herein.

This application may contain material that is subject to copyright, mask work, and/or other intellectual property protection. The respective owners of such intellectual property have no objection to the facsimile reproduction of the disclosure by anyone as it appears in published Patent Office file/records, but otherwise reserve all rights.

The disclosed embodiments provide systems, methods, and modes for providing a rotational soundbar mounting apparatus that couples to a display wall mounting system and which rotationally mounts a soundbar to the display according to aspects of the embodiments. It should be understood that this description is not intended to limit the embodiments. On the contrary, the embodiments are intended to cover alternatives, modifications, and equivalents, which are included in the spirit and scope of the embodiments as defined by the appended claims. Further, in the detailed description of the embodiments, numerous specific details are set forth to provide a comprehensive understanding of the claimed embodiments. However, one skilled in the art would understand that various embodiments may be practiced without such specific details.

Although the features and elements of aspects of the embodiments are described being in particular combinations, each feature or element can be used alone, without the other features and elements of the embodiments, or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

The above-described embodiments are intended to be illustrative in all respects, rather than restrictive, of the embodiments. Thus, the embodiments are capable of many variations in detailed implementation that can be derived from the description contained herein by a person skilled in the art. No element, act, or instruction used in the description of the present application should be construed as critical or essential to the embodiments unless explicitly described as such. Also, as used herein, the article “a” is intended to include one or more items.

All United States patents and applications, foreign patents, and publications discussed above are hereby incorporated herein by reference in their entireties.

### INDUSTRIAL APPLICABILITY

To solve the aforementioned problems, the aspects of the embodiments are directed towards systems, methods, and modes for providing a rotational soundbar mounting apparatus that couples to a display wall mounting system and which rotationally mounts a soundbar to the display according to aspects of the embodiments.

### ALTERNATE EMBODIMENTS

Alternate embodiments may be devised without departing from the spirit or the scope of the different aspects of the embodiments.

What is claimed is:

1. A rotational soundbar mounting apparatus for supporting a soundbar relative to a display, the apparatus comprising:
a first rail coupled to the display;
a rotational soundbar bracket coupled to the first rail, wherein the rotational soundbar bracket includes a soundbar mounting surface and a mounting interface, wherein the soundbar mounting surface includes a rotating pin receptacle and a plurality of locking pin receptacles positioned concentrically around the rotating pin receptacle;
a soundbar mounting bracket coupled to the mounting interface of the rotational soundbar bracket and coupled to the soundbar;
a rotating pin inserted into the rotating pin receptacle to define a rotational axis about which the rotational soundbar bracket is rotatable relative to the first rail; and
a locking pin inserted into a selected one of the plurality of locking pin receptacles to restrict rotation of the rotational soundbar bracket relative to the first rail and maintain the rotational soundbar bracket at a selected angular position.

2. The apparatus of claim 1, wherein the first rail includes a rail rotating hole and a rotation locking hole, wherein the rotating pin extends through the rotating hole and is received by the rotating pin receptacle, and wherein the locking pin extends through the rotation locking hole and the selected one of the plurality of locking pin receptacles.

3. The apparatus of claim 1, wherein the first rail includes a plurality of substantially circular shaped holes configured to receive fasteners for coupling the first rail to at least one of a wall, the display, a second rail, or another supporting structure.

4. The apparatus of claim 1, further comprising a second rail configured to be coupled to the rear side of the display, wherein the first rail is coupled to the second rail by fasteners extending through a plurality of substantially circular shaped holes of the first rail and through a plurality of oval shaped holes of the second rail that overlap the plurality of substantially circular shaped holes.

5. The apparatus of claim 4, wherein the oval shaped holes permit positional adjustment of the first rail relative to the second rail prior to fully tightening the fasteners.

6. The apparatus of claim 1, wherein the plurality of locking pin receptacles are arranged along an imaginary circle centered on the rotational axis defined by the rotating pin receptacle.

7. The apparatus of claim 6, wherein the plurality of locking pin receptacles are positioned at a substantially common radial distance from the rotational axis.

8. The apparatus of claim 1, wherein the plurality of locking pin receptacles define predetermined angular positions of the rotational soundbar bracket with respect to the rotational axis.

9. The apparatus of claim 1, wherein the plurality of locking pin receptacles includes a first, a second, and a third locking pin receptacle, wherein a first imaginary line extends through the second locking pin receptacle and the rotating pin receptacle, wherein the first locking pin receptacle is offset from the first imaginary line in a first transverse direction by a first offset angle, and the third locking pin receptacle is offset from the first imaginary line in a second transverse direction opposite the first transverse direction by a second offset angle.

10. A rotational soundbar bracket comprising:
a soundbar mounting surface;
a mounting bracket interface connected to the soundbar mounting surface;
a rotating pin receptacle disposed on the soundbar mounting surface and configured to receive a rotating pin that defines a rotation axis about which the rotational soundbar bracket is rotatable relative to a supporting component; and
a plurality of locking pin receptacles disposed on the soundbar mounting surface at different angular locations relative to the rotating pin receptacle, wherein the plurality of locking pin receptacles is adapted to selectively receive a locking pin to restrict rotation of the rotational soundbar bracket relative to the supporting component and maintain the rotational soundbar bracket at a selected angular position.

11. The rotational soundbar bracket of claim 10, wherein the mounting interface includes a first mounting hole and a second mounting hole adapted to receive fasteners to couple the rotational soundbar bracket to a soundbar mounting bracket.

12. The rotational soundbar bracket of claim 11, wherein the first mounting hole and the second mounting hole are aligned with one another along a longitudinal direction of the mounting interface.

13. The rotational soundbar bracket of claim 10, wherein the soundbar mounting surface is substantially perpendicular to the mounting bracket interface.

14. The rotational soundbar bracket of claim 10, wherein the rotating pin receptacle protrudes outwardly from the soundbar mounting surface to receive the rotating pin.

15. The rotational soundbar bracket of claim 10, wherein the plurality of locking pin receptacles are disposed at a substantially common radial distance from the rotational axis defined by the rotating pin receptacle.

16. A rotational soundbar mounting apparatus for supporting a soundbar relative to a display, the apparatus comprising:
a first rail coupled to the display;
a rotational soundbar bracket coupled to the first rail, wherein the rotational soundbar bracket includes a soundbar mounting surface and a mounting bracket interface, wherein the soundbar mounting surface includes a rotating pin receptacle and a curved locking pin slot;
a soundbar mounting bracket coupled to the mounting bracket interface of the rotational soundbar bracket and coupled to the soundbar;
a rotating pin inserted into the rotating pin receptacle to define a rotational axis about which the rotational soundbar bracket is rotatable relative to the first rail; and
a locking pin inserted into the curved locking pin slot to restrict rotation of the rotational soundbar bracket relative to the first rail and maintain the rotational soundbar bracket at a selected angular position.

17. The rotational soundbar mounting apparatus of claim 16, wherein the curved locking pin slot is arcuate about the rotational axis defined by the rotating pin receptacle such that the curved locking pin slot is concentric with the rotational axis.

18. The rotational soundbar mounting apparatus of claim 16, wherein the soundbar mounting surface includes a first curved locking pin slot and a second curved locking pin slot, and wherein the locking pin is configured to be inserted into a selected one of the first curved locking pin slot or the second curved locking pin slot to set the rotational soundbar bracket to the selected angular position.

19. The rotational soundbar mounting apparatus of claim 16, wherein the curved locking pin slot defines a substantially continuous angular adjustment range for the rotational soundbar bracket, and wherein the selected angular position of the rotational soundbar bracket is continuously selectable within the angular adjustment range by selecting an engagement position of the locking pin along a length of the curved locking pin slot.

20. The rotational soundbar mounting apparatus of claim 16, wherein the first rail includes a rotation locking hole, and wherein the locking pin extends through the rotation locking hole and the curved locking pin slot to restrict rotation of the rotational soundbar bracket relative to the first rail.
